(19) United States
(12) Patent Application Publication
(10) Pub. No.: US 2018/0182947 A1
(43) Pub. Date: Jun. 28, 2018

(54) THERMOELECTRIC CONVERSION DEVICE

(71) Applicant: FUJIFILM Corporation, Tokyo (JP)

(72) Inventors: Shinji IMAI, Ashigara-kami-gun (JP); Hideyuki SUZUKI, Ashigara-kami-gun (JP)

(73) Assignee: FUJIFILM Corporation, Tokyo (JP)

(21) Appl. No.: 15/902,107

(22) Filed: Feb. 22, 2018

Related U.S. Application Data
(63) Continuation of application No. PCT/JP2016/074362, filed on Aug. 22, 2016.

(30) Foreign Application Priority Data
Aug. 31, 2015 (JP) 2015-170643
May 31, 2016 (JP) 2016-108119

(51) Int. Cl. H01L 35/32; H01L 35/34

(52) U.S. Cl. CPC H01L 35/32; H01L 35/34

(57) ABSTRACT

Provided is a thermoelectric conversion device which is highly self-supportive, is easily installable in heat sources of various shapes, and is highly installable, This thermoelectric conversion device includes a bellows-like module band which includes an insulating substrate, a plurality of thermoelectric conversion layers arranged at intervals set in advance on a principal surface of the insulating substrate, and a plurality of wiring members arranged to sandwich each of the thermoelectric conversion layers therebetween on the principal surface of the insulating substrate, is alternately mountain-folded or valley-folded and formed in a bellows structure, and has a plurality of through holes formed in each of a plurality of plate-like portions formed by bellows-like folding of the insulating substrate, and a linear member which transects the plurality of plate-like portions and is inserted into the plurality of through holes.

### CROSS-REFERENCE TO RELATED APPLICATIONS

This application is a Continuation of PCT International Application No. PCT/JP2016/074362 filed on Aug. 22, 2016, which claims priority under 35 U.S.C. § 119(a) to Japanese Patent Application No. 2015-170643 filed on Aug. 31, 2015 and Japanese Patent Application No. 2016-108119 filed on May 31, 2016. Each of the above applications is hereby expressly incorporated by reference, in its entirety, into the present application.

### BACKGROUND OF THE INVENTION

### 1. Field of the Invention

The present invention relates to a thermoelectric conversion device using a plurality of thermoelectric conversion elements.

### 2. Description of the Related Art

Thermoelectric conversion materials capable of converting heat energy to electrical energy and vice versa are used in thermoelectric conversion elements such as power generation elements or Peltier elements which generate power using heat.

Thermoelectric conversion elements are capable of directly converting heat energy to electric power and, advantageously, do not require any movable portions. Therefore, thermoelectric conversion modules (power generation devices) obtained by connecting a plurality of thermoelectric, conversion elements are capable of easily obtaining electric power without the need of operation costs by being provided in, for example, heat discharging portions of incineration furnaces, various facilities in plants, and the like.

As such a thermoelectric conversion element, a so-called π-type thermoelectric conversion element is known.

A π-type thermoelectric conversion element has a configuration in which a pair of electrodes that are arranged apart from each other is provided, and an N-type thermoelectric conversion material is provided on one of the electrodes, while a P-type thermoelectric conversion material is provided on the other electrode, such that the thermoelectric conversion materials are similarly arranged apart from each other, with the top surfaces of the two thermoelectric conversion materials being connected to each other through the electrodes.

In addition, a plurality of thermoelectric conversion elements are arranged such that the N-type thermoelectric conversion material and the P-type thermoelectric conversion material are alternately arranged, and the electrodes in a portion underneath the thermoelectric conversion materials are connected to each other in series. Thus, a thermoelectric conversion module is formed.

Typical thermoelectric conversion elements including a π-type thermoelectric conversion element have a configuration in which an electrode is provided on a sheet-like substrate, a thermoelectric conversion layer (power generation layer) is provided on the electrode, and a sheet-like electrode is provided on the thermoelectric conversion layer.

That is, in typical thermoelectric conversion elements, a thermoelectric conversion layer is sandwiched between electrodes in a thickness direction, and a temperature difference is generated in the thickness direction of the thermoelectric conversion layer, thereby converting heat energy to electrical energy.

However, in manufacturing for connecting a large number of such π-type thermoelectric conversion elements, there is a problem of making the manufacturing step complicated and requiring much time and labor. In addition, there is a problem that an influence of thermal strain or a change in thermal strain due to a difference in thermal expansion coefficient of each member is repeatedly generated to easily cause a fatigue phenomenon at the interface, thereby resulting in performance deterioration.

In contrast, JP2014-33114A discloses a thermoelectric conversion device having a plurality of thermoelectric conversion elements (thermoelectric conversion modules) including a hand-shaped flexible insulating substrate element (insulating substrate), thermoelectric conversion material members (thermoelectric conversion layers) which are formed on the insulating substrate element with intervals, and a wiring (wiring member) which mutually connects thermoelectric conversion material members adjacent to each other at an upper end portion and a lower end portion. The thermoelectric conversion device comes into contact with a heat source in the end surface of the insulating substrate and a temperature difference is generated in a plane direction of the thermoelectric conversion layer (insulating substrate) to convert heat energy to electrical energy.

Since the thermoelectric conversion module disclosed in JP2014-33114A is formed such that the thermoelectric conversion layer and the wiring member are arranged in the plane direction of the substrate, the thermoelectric conversion module is easily manufactured, a problem of an influence of thermal strain due to a difference in thermal expansion coefficient of each member or the like does not easily arise, and performance deterioration caused by a fatigue phenomenon at the interface can be suppressed.

In addition, JP2014-33114A discloses that in order to achieve high output density of the thermoelectric conversion device, the plurality of thermoelectric conversion modules are overlapped and each thermoelectric conversion module is electrically connected to an adjacent thermoelectric conversion module at the end portion of each thermoelectric conversion module.

In addition, JP2013-225550A discloses that a plurality of thermoelectric conversion elements (thermoelectric conversion modules) in which a thermoelectric conversion member (thermoelectric conversion element) is formed on a substrate element (insulating substrate) having a conductive through-via (through hole) are laminated, and the thermoelectric conversion elements of the laminated thermoelectric conversion modules are electrically connected to each other through the through-via.

### SUMMARY OF THE INVENTION

Since a thermoelectric conversion device in which an end surface of an insulating substrate is brought into contact with a heat source by overlapping a plurality of thermoelectric conversion modules is installed on the heat source using the end surface as a bottom surface, there is a problem of low self-supporting properties and poor installation properties. In order to improve self-supporting properties, it is considered to fix the thermoelectric conversion modules to each other. However, in a case where the thermoelectric conversion modules are fixed to each other, flexibility is decreased. For example, in a case where a member having a curved surface, such as a pipe, is used as a heat source and the thermoelectric conversion device is installed on the heat source, it is necessary to fix the plurality of thermoelectric conversion modules along the curved shape of the surface of the pipe in advance. Therefore, the thermoelectric conversion device cannot be applied to heat sources of various shapes.

An object of the present invention is to solve the above problems of the related art and to provide a thermoelectric conversion device which is highly self-supportive, is easily installable in heat sources of various shapes, and is highly installable.

As a result of intensive investigations to achieve the above object, the present inventors have found that the above problems can be solved by providing a bellows-like module band which includes an insulating substrate, a plurality of thermoelectric conversion layers arranged at intervals set in advance on a principal surface of the insulating substrate, and a plurality of wiring members arranged to sandwich each of the thermoelectric conversion layers therebetween on the principal surface of the insulating substrate, is alternately mountain-folded or valley-folded and formed in a bellows structure, and has a plurality of through holes formed in each of a plurality of plate-like portions formed by bellows-like folding of the insulating substrate, and a flexible linear member which transects the plurality of plate-like portions and is inserted into the plurality of through holes, and thus have completed the present invention.

That is, the present invention provides the following thermoelectric conversion device.

(1) A thermoelectric conversion device comprising: a bellows-like module band which includes an insulating substrate, a plurality of thermoelectric conversion layers arranged at intervals set in advance on a principal surface of the insulating substrate, and a plurality of wiring members arranged to sandwich each of the thermoelectric conversion layers therebetween on the principal surface of the insulating substrate, is alternately mountain-folded or valley-folded and formed in a bellows structure, and has a plurality of through holes formed in each of a plurality of plate-like portions formed by bellows-like folding of the insulating substrate; and a linear member which transects the plurality of plate-like portions and is inserted into the plurality of through holes.

(2) The thermoelectric conversion device according to (1), in which the plurality of plate-like portions are pressed in a lamination direction by the linear member.

(3) The thermoelectric conversion device according to (1) or (2), further comprising: a heat transfer member which is arranged between at least some of the plate-like portions adjacent to each other.

(4) The thermoelectric conversion device according to any one of (1) to (3), further comprising: magnets which are arranged in a direction in which the plurality of plate-like portions are laminated to sandwich the bellows-like module band therebetween.

(5) The thermoelectric conversion device according to any one of (1) to (4), in which the through hole is formed in a place of the plate-like portion other than a position where the thermoelectric conversion layer is formed.

(6) The thermoelectric conversion device according to any one of (1) to (5), in which the through hole is formed in a place of the plate-like portion other than a position where the wiring member is formed.

(7) The thermoelectric conversion device according to any one of (1) to (6), in which as seen from the direction in which the plurality of plate-like portions are laminated, the plurality of through holes formed in each of the plate-like portions are formed at positions where the through holes are overlapped each other.

(8) The thermoelectric conversion device according to any one of (1) to (7), in which each of the plate-like portions has two or more through holes, and two or more linear members which are respectively inserted into each of the through holes of the plate-like portions are provided.

(9) The thermoelectric conversion device according to any one of (1) to (8), in which the through hole is formed on a mountain fold side or a valley fold side of the plate-like portion.

(10) The thermoelectric conversion device according to any one of (1) to (9), in which the plurality of thermoelectric conversion layers include a P-type thermoelectric conversion layer and an N-type thermoelectric conversion layer, any one of the P-type thermoelectric conversion layer and the N-type thermoelectric conversion layer is alternately formed on each of the plurality of plate-like portions on one surface of the insulating substrate according to the bellows-like folding, and the wiring member connects the P-type thermoelectric conversion layer and the N-type thermoelectric conversion layer adjacent to each other.

(11) The thermoelectric conversion device according to any one of (1) to (9), in which the plurality of thermoelectric conversion layers are arranged on each of the plate-like portions in a direction parallel to a folded ridgeline of the insulating substrate.

According to the present invention, it is possible to provide a thermoelectric conversion device which is highly self-supportive, is easily installable in heat sources of various shapes, and is highly installable.

### BRIEF DESCRIPTION OF THE DRAWINGS

FIG. 1 is a perspective view conceptually showing an example of a thermoelectric conversion device of the present invention.

FIG. 2 is a cross-sectional view taken along line A-A in FIG. 1.

FIG. 3 is a conceptual view for illustrating a module main body.

FIG. 4 is a cross-sectional view conceptually showing another example of the thermoelectric conversion device of the present invention.

FIG. 5 is a cross-sectional view conceptually showing still another example of the thermoelectric conversion device of the present invention.

FIG. 6 is a cross-sectional view conceptually showing an example in which the thermoelectric conversion device in FIG. 5 is arranged on a heat source.

FIG. 7 is a cross-sectional view conceptually showing still another example of the thermoelectric conversion device of the present invention.

FIG. 8 is a cross-sectional view conceptually showing an example in which the thermoelectric conversion device in FIG. 7 is arranged on a heat source.

FIG. 9A is a cross-sectional view conceptually showing an example of the thermoelectric conversion device.

FIG. 9B is an enlarged view showing a portion as FIG. 9A is seen from a direction b.

FIG. 9C is a view for illustrating electrical connection of the thermoelectric conversion device.

FIG. 10 is view conceptually showing still another example of the thermoelectric conversion device.

FIG. 11A is a view for illustrating a step of an example of a method of producing a thermoelectric conversion device.

FIG. 11B is a view for illustrating a step of the example of the method of producing a thermoelectric conversion device.

FIG. 11C is a view for illustrating a step of the example of the method of producing a thermoelectric conversion device.

FIG. 12A is a view for illustrating a step of the example of the method of producing a thermoelectric conversion device.

FIG. 12B is a view for illustrating a step of the example of the method of producing a thermoelectric conversion device.

FIG. 13 is a view for illustrating a step of the example of the method of producing a thermoelectric conversion device.

FIG. 14A is a view for illustrating a step of the example of the method of producing a thermoelectric conversion device.

FIG. 14B is a view for illustrating a step of the example of the method of producing a thermoelectric conversion device.

FIG. 14C is a view for illustrating a step of the example of the method of producing a thermoelectric conversion device.

FIG. 14D is a view for illustrating a step of the example of the method of producing a thermoelectric conversion device.

### DESCRIPTION OF THE PREFERRED EMBODIMENTS

Hereinafter, a thermoelectric conversion device of the present invention will be described in detail based on preferable embodiments shown in the accompanying drawings.

In the following description, “to” indicating a numerical value range includes numerical values described on both sides. For example, when ε is a numerical value a to a numerical value β, the range of ε is a range including the numerical value α and the numerical value β, and is represented as α≤ε≤β using mathematical symbols.

Unless otherwise specified, an angle means that a difference from the exact angle falls within a range of less than 5°. The difference from the exact angle is preferably less than 4° and more preferably less than 3°.

The meaning of “the same” includes an error range that is generally allowable in the technical field. In addition, the meaning of “entire surface” and the like includes not only 100% but also a case where an error range is generally allowable in the technical field, for example, 99% or more, 95% or more, or 90% or more.

A thermoelectric conversion device of the present invention is a thermoelectric conversion device including a thermoelectric conversion module which includes an insulating substrate, a plurality of thermoelectric conversion layers arranged at intervals set in advance on a principal surface of the insulating substrate, and a plurality of wiring members arranged to sandwich each of the thermoelectric conversion layers therebetween on the principal surface of the insulating substrate, is alternately mountain-folded or valley-folded and formed in a bellows structure, and has a plurality of through holes formed in each of a plurality of plate-like portions by bellows-like folding of the insulating substrate, and

a linear member which transects the plurality of plate-like portions and inserts the plurality of through holes.

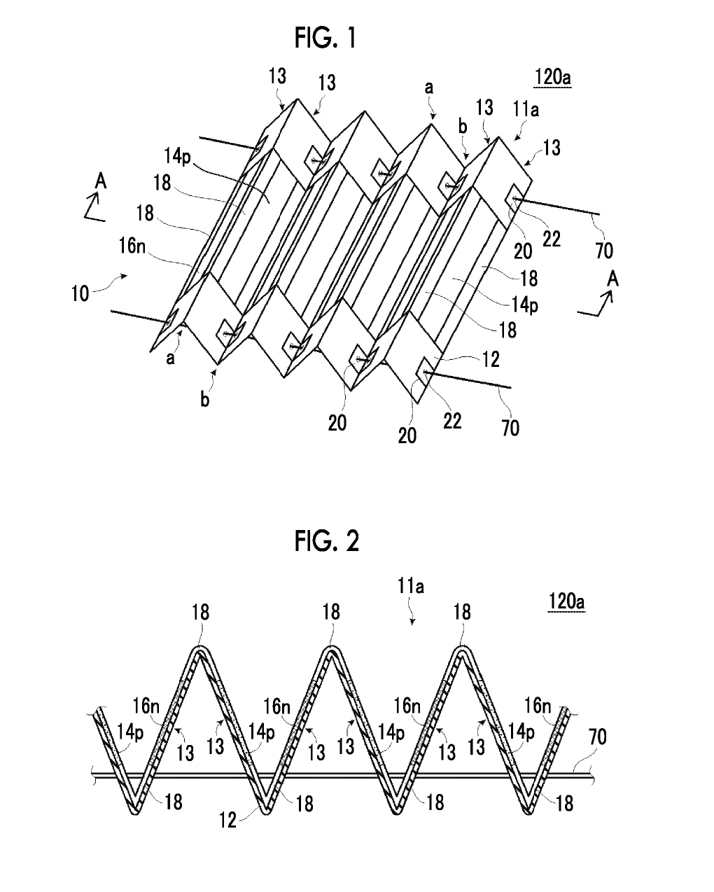

FIG. 1 is a perspective view conceptually showing an example of a thermoelectric conversion device of the present invention, and FIG. 2 is a cross-sectional view taken along line A-A in FIG. 1.

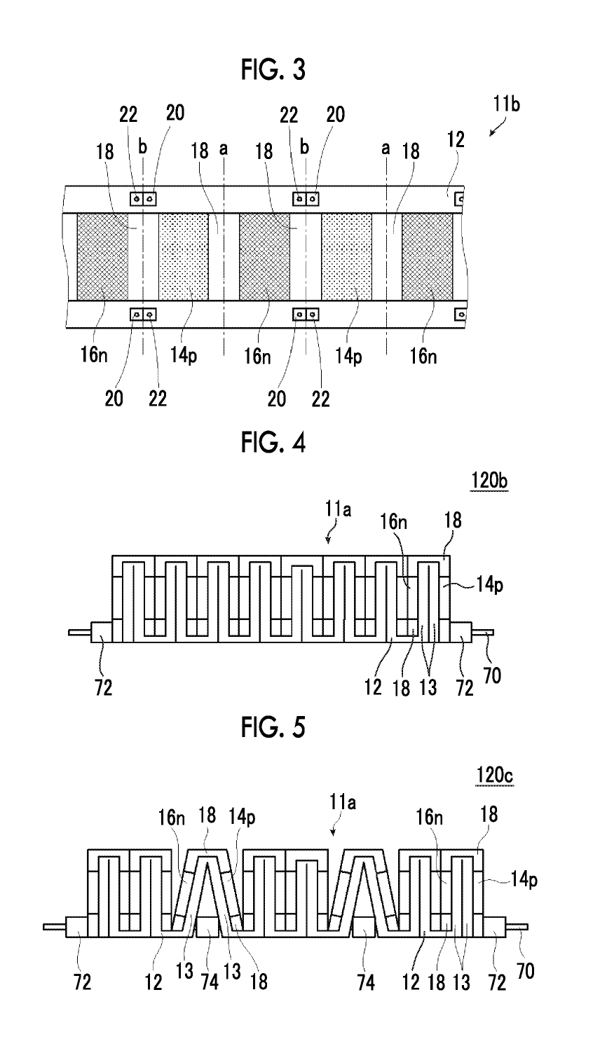

A thermoelectric conversion device 120a shown in FIGS. 1 and 2 has a bellows-like module band 11a and a wire 70. The bellows-like module band 11a corresponds to a thermoelectric conversion module band in the present invention, and the wire 70 corresponds to a linear member in the present invention. In FIG. 2, in order to clearly show the configuration, the insulating substrate 12 is indicated by a hatched line, a P-type thermoelectric conversion layer 14p and an N-type thermoelectric conversion layer 16n are indicated by half-tone dot meshing, and hatching of a wiring member 18 is omitted. Regarding the meshing of the P-type thermoelectric conversion layer 14p and the N-type thermoelectric conversion layer 16n, the same is applied to FIG. 3.

The bellows-like module band 11a has the insulating substrate 12, the P-type thermoelectric conversion layer 14p, the N-type thermoelectric conversion layer 16n, a reinforcing member 20, and a through hole 22.

FIG. 3 shows a top view of a module band 11b in a state in which mountain folds and valley folds of the bellows-like module band 11a are extended and formed in a plane shape.

As shown in FIG. 3, the module band 11b has a configuration in which the P-type thermoelectric conversion layer 14p and the N-type thermoelectric conversion layer 16n are alternately arranged in a longitudinal direction of the insulating substrate 12 (hereinafter, also simply referred to as “longitudinal direction”) on a principal surface of the insulating substrate 12 at predetermined intervals, and the wiring member 18 which electrically connects the P-type thermoelectric conversion layer 14p and the N-type thermoelectric conversion layer 16n is arranged between the P-type thermoelectric conversion layer 14p and the N-type thermoelectric conversion layer 16n.

In addition, a plurality of through holes 22 are formed in a predetermined pattern in a region on the insulating substrate 12 in which the P-type thermoelectric conversion layer 14p, the N-type thermoelectric conversion layer 16n, and the wiring member 18 are not arranged. In the example shown in the drawing, the P-type thermoelectric conversion layer 14p, the N-type thermoelectric conversion layer 16n, and the wiring member 18 are arranged at the center portion in a width direction orthogonal to the longitudinal direction of the insulating substrate 12 (hereinafter, also simply referred to as “width direction”), and the through holes 22 are formed on both end portion sides in which these members are not arranged.

In addition, in order to prevent a decrease in strength of the insulating substrate 12 due to formation of the through holes, the reinforcing members 20 are arranged on the peripheral edge portions of the positions in which the through holes 22 are formed.

In such a module band 11b, in the longitudinal direction, the module band is alternately mountain-folded or valley-folded at the position of each wiring member 18. In the example shown in FIG. 3, in the drawing, a line which is indicated by a dashed line a and extends in the width direction is a ridgeline of a mountain told and a line which is indicated by a dashed line b and extends in the width direction is a ridgeline of a valley fold.

By mountain-folding the module band 11b along the dashed line a or valley-folding the module band along the dashed line b, as shown in FIGS. 1 and 2, the bellows-like module band 11a in which the insulating substrate 12 is alternately folded can be formed.

Accordingly, the bellows-like module band 11a has a mountain fold portion and a valley fold portion alternately in the longitudinal direction by bellows-like folding, and a top portion of the mountain fold portion (indicated by an arrow a in FIG. 1) and a bottom portion of the valley fold portion (indicated by an arrow b in FIG. 1) are alternately provided. That is, the portion of the module band 11b indicated by the dashed line a is a top portion a of the bellows-like module band 11a and the portion of the module band 11b indicated by the dashed line b is a bottom portion b of the bellows-like module hand 11a.

In the example, by bellows-like folding, the insulating substrate 12 is set as arm inner side, that is, a side on which the wiring member 18 becomes convex is set to a mountain fold portion and the insulating substrate 12 is set as an outer side, that is, a side on which the wiring member 18 becomes concave is set to a valley fold portion. That is, the upper side in FIG. 1 is set to a mountain fold portion and the lower side in the drawing is set to a valley fold portion.

In the following description, each region between the top portion a and the bottom portion b of the insulating substrate 12 is referred to as the plate-like portion 13. That is, the insulating substrate 12 folded in a bellows-like shape can be referred to as a structure in which the plurality of plate-like portions 13 are connected to each other in a bellows-like shape.

In the bellows-like module band 11a shown in FIGS. 1 and 2, one thermoelectric conversion layer (P-type thermoelectric conversion layer 14p or N-type thermoelectric conversion layer 16n), and the wiring members 18 arranged so as to sandwich the thermoelectric conversion layer are formed on each of the plurality of plate-like portions 13 which are formed by bellows-like folding. That is, one thermoelectric conversion layer and the wiring members 18 which sandwich the thermoelectric conversion layer constitutes one thermoelectric conversion element, and one plate-like portion 13 and one thermoelectric conversion element (one thermoelectric conversion layer and the wiring members 18 which sandwich the thermoelectric conversion layer therebetween) constitute one thermoelectric conversion module. Accordingly, the bellows-like module band 11a can have a configuration in which a plurality of thermoelectric conversion modules each having the plate-like portion 13, the thermoelectric conversion layer, and the wiring members 18 are connected to each other in a bellows-like shape.

In the following description, in a case where there is no need to distinguish the P-type thermoelectric conversion layer 14p and the N-type thermoelectric conversion layer 16n, the thermoelectric conversion layer are collectively referred to as a thermoelectric conversion layer.

Each thermoelectric conversion module configured as described above is a thermoelectric conversion module which comes into contact with a heat source in the end surface of the insulating substrate to generate a temperature difference in the plane direction of the thermoelectric conversion layer (insulating substrate), thereby converting heat energy to electrical energy.

In addition, as described above, in the region of the insulating substrate 12 in which the thermoelectric conversion layer and the wiring member 18 are not arranged, the through hole 22 is formed.

Specifically, in the example shown in FIG. 1, two through holes 22 are formed in each plate-like portion 13, and two through holes 22 are respectively formed on the bottom portions b (valley fold portions) sides of both end portion sides of the plate-like portion 13 in the width direction. In addition, in a case where the bellows of the bellows-like module band Fla is opened and the plate-like portions 13 are laminated, the through holes 22 formed in each plate-like portion 13 are formed at the positions where the through holes are overlapped each other as seen from the lamination direction of the plate-like member, that is, at the same position.

One wire 70 transects the plurality of plate-like portions 13 and is inserted into the through holes 22 of each plate-like portion 13 formed at the same position. In the example shown in FIG. 1, since two through holes 22 are formed in each plate-like portion 13, the wire 70 is inserted into each of two through holes 22 of each plate-like portion 13. That is, the thermoelectric conversion device 120a shown in FIG. 1 has two wires 70.

The thermoelectric conversion device 120a configured as described above is arranged such that at least one of the top portion a (mountain fold portion) or the bottom portion h (valley fold portion) comes into contact with a heat source. Thus, a temperature difference in the thermoelectric conversion layer (insulating substrate) in the plane direction is generated and heat energy is converted into electrical energy. In the example shown in FIG. 1, the P-type thermoelectric conversion layer 14p and the N-type thermoelectric conversion layer 16n are alternately arranged on each plate-like portion 13 and are connected to each other in series by the wiring member 18. Therefore, the P-type thermoelectric conversion layer 14p and the N-type thermoelectric conversion layer 16n generate an electromotive force mutually in the opposite direction to a direction in which a temperature difference is generated. For example, the P-type thermoelectric conversion layer 14p generates an electromotive force so as to cause a current to flow in the upper direction in FIG. 1 and the N-type thermoelectric conversion layer 16n generates an electromotive force so as to cause a current to flow in the upper direction in FIG. 1. Accordingly, in the electrical connection direction, the electromotive force of the P-type thermoelectric conversion layer 14p and the electromotive force of the N-type thermoelectric conversion layer 16n are in the same direction and the bellows-like module band 11a can obtain a large electromotive force.

Since the end surface of the thermoelectric conversion device which comes into contact a heat source in the end portion of the insulating substrate by overlapping the plurality of thermoelectric conversion modules as described above is installed on the heat source as a bottom surface, there is a problem of low self-supporting properties and poor installation properties. In order to improve self-supporting properties, it is considered to fix the thermoelectric conversion modules to each other. However, in a case where the thermoelectric conversion modules are fixed to each other, flexibility is decreased. For example, in a case where a member having a curved surface, such as a pipe, is used as a heat source and the thermoelectric conversion device is installed on the heat source, it is necessary to fix the plurality of thermoelectric conversion modules along the curved surface of the pipe in advance. Therefore, there is a problem that the thermoelectric conversion device cannot be applied to heat sources of various shapes.

In contrast, since the module band is formed in a bellows-like shape in the thermoelectric conversion device 120a of the present invention, only by arraigning the top portion a or the bottom portion b of the bellows-like module band 11a on a heat source such that top portion or the bottom portion comes into contact with the heat source, and the thermoelectric conversion module constituted by the plate-like portion 13, the thermoelectric conversion layer, and the wiring member 18 can be held substantially perpendicular to the installation surface of the heat source in a state in which the end surface of the plate-like portion 13 is brought into contact with the heat source.

In addition, since the module band is formed in a bellows-like shape, in a case where a member having a curved surface, such as a pipe, is used as a heat source and the thermoelectric conversion device 120a is installed on the heat source, the thermoelectric conversion device can be appropriately arranged such that the bellows structure of the bellows-like module band 11a is deformed according to the curved shape of the heat source surface and the top portion a or the bottom portion h of the bellows-like module band 11a comes into contact with the heat source. At this time, by connecting and fixing the both end portions of the wire 70, the shape of the bellows structure can be held in a shape formed along the curved shape of the heat source surface.

Further, since the module band is formed in a bellows-like shape and can be easily deformed, the thermoelectric conversion device can be appropriately installed such that the bellows structure is deformed according to heat sources of various shapes respectively and the top portion a or the bottom portion b of the bellows-like module band 11a comes into contact with the heat source.

In this manner, the thermoelectric conversion device of the present invention is highly self-supportive, is easily installable on heat sources of various shapes, and is highly installable.

Here, in the example shown in FIG. 1, the configuration in which the wire 70 is only inserted into the through hole 22 formed in each plate-like portion 13 of the bellows-like module band 11a is adopted but there is no limitation thereto. A configuration in which the plurality of plate-like portions 13 are pressed by the wire 70 inserted into the through hole 22 in the lamination direction thereof may be adopted.

FIG. 4 is a cross-sectional view conceptually showing another example of the thermoelectric conversion device of the present invention,

A thermoelectric conversion device 120b shown in FIG. 4 has the same configuration as the thermoelectric conversion device 120a shown in Fig. I except that an end portion fixing member 72 is provided. Thus, the same symbols are attached to the same constitutional elements and the detailed descriptions thereof are omitted.

The thermoelectric conversion device 120b shown in FIG. 4 includes a bellows-like module band 11a having an insulating substrate 12 formed in a bellows-like shape, a thermoelectric conversion layer (P-type thermoelectric conversion layer 14p or N-type thermoelectric conversion layer 16n) formed on each of a plurality of plate-like portions 13 by bellows-like folding of the insulating substrate 12, a wiring member 18, and through holes 22 (not shown) formed in each of the plate-like portions 13, a wire 70 inserted into the plurality of through holes 22 formed in each of the plurality of plate-like portions 13, and two end portion fixing members 72 fixed at end portions of the wire 70 arranged on both surface of the plurality of laminated plate-like portions 13.

The end portion fixing member 72 is a block-like member and has a through hole (not shown) into which the wire 70 is inserted on one surface thereof. As shown in the drawing, the two end portion fixing members 72 are made in a state in which the bellows of the bellows-like module band 11a is completely folded by pressing the both surfaces of the bellows-like module band 11a (hereinafter, also referred to as “closed state”) and are fixed to the wire 70.

Thus, the state in which the bellows of the bellows-like module band 11a is closed can be maintained and the thermoelectric conversion module can be densified. In addition, it is possible to prevent the wire 70 from coming out from the through hole 22 of the bellows-like module band 11a.

A method of fixing the end portion fixing member 72 and the wire 70 is not limited and for example, various known fixing methods such as a method of filling the through hole of the end portion fixing member 72 into which the wire 70 is inserted with an adhesive for fixing, a method of providing a knot formed by knotting the end portions of the wire 70 inserted into the through hole of the end portion fixing member 72 to lock the end portion fixing member 72, and the like can be appropriately used.

In addition, in a case where the bellows of the bellows-like module band 11a is completely folded, a heat transfer member may be provided between the laminated plate-like portions 13.

FIG. 5 is a cross-sectional view conceptually showing still another example of the thermoelectric conversion device of the present invention.

A thermoelectric conversion device 120c shown in FIG. 5 has the same configuration as the thermoelectric conversion device 120b shown in FIG. 4 except that a heat transfer member 74 is provided. Thus, the same symbols are attached to the same constitutional elements and the detailed descriptions thereof are omitted.

The thermoelectric conversion device 120c shown in FIG. 5 includes a bellows-like module band 11a having an insulating substrate 12 formed in a bellows-like shape, a thermoelectric conversion layer (P-type thermoelectric conversion layer 14p or N-type thermoelectric conversion layer 16n) formed in each of a plurality of plate-like portions 13 by bellows-like folding of the insulating substrate 12, a wiring member 18, and through holes 22 (not shown) formed in each of the plate-like portions 13, a wire 70 inserted into the plurality of through holes 22 formed on each of the plurality of plate-like portions 13, two end portion fixing members 72 fixed at end portions of the wire 70 arranged on both surface of the plurality of laminated plate-like portions 13, and a heat transfer member 74 which is arranged between at least sonic of the plate-like portions 13 and into which the wire 70 is inserted.

The heat transfer member 74 is a block-like member formed of a material having high thermal conductivity and has a through hole (not shown) into which the wire 70 is inserted on one surface thereof is inserted. In the example shown in the drawing, the heat transfer member 74 is arranged between a fifth plate-like portion 13 and a sixth plate-like portion 13 from each of both end portions of the bellows-like module band 11a.

Accordingly, the thermoelectric conversion device 120c has a configuration in which the bellows of the bellows-like module band 11a is folded by arranging the heat transfer member 74 between at least some of the plate-like portions 13 and pressing the bellows-like module band 11a by the two end portion fixing members 72 from the both end surfaces and fixing the bellows-like module(band to the wire 70.

In a case of a configuration in which the plurality of thermoelectric conversion modules are overlapped, insulating substrates formed of a material having a low thermal conductivity, such as polyimide, are overlapped and thus a temperature difference is not easily generated in the thermoelectric conversion module positioned in the inner side of the bellows-like module band in a case of overlapping the insulating substrates. Therefore, the power generation amount of the thermoelectric conversion device may be decreased.

In contrast, in a case where the bellows-like module band 11a is pressed by the two end portion fixing members 72 from the both end surfaces and fixed to the wire 70, and the bellows of the bellows-like module band 11a is folded, by arranging the heat transfer member 74 between at least some of the plate-like portions 13, heat can be reliably transferred to the thermoelectric conversion module positioned in the inner side of the bellows-like module hand through the heat transfer member 74. Accordingly, a large temperature difference can be generated in the thermoelectric conversion module positioned in the inner side of the bellows-like module band, and the power generation amount of the thermoelectric conversion device can be increased.

In addition, by arranging the heat transfer member 74 between at least some of the plate-like portions 13, the plate-like portions 13 (thermoelectric conversion modules) do not easily fall down and the plate-like portions 13 can be more suitably held in a state of being substantially perpendicular to the installation surface.

The arrangement interval of the heat transfer member 74b is not limited and the heat transfer member 74 may be arranged between the plate-like portions 13 at every other plate-like portion, may be arranged at an interval of two or more plate-like portions, or may be arranged between all of the plate-like portions 13.

As described above, since the module hand is formed in a bellows-like shape, in a case where the thermoelectric conversion device of the present invention is installed on a member (heat source) having a curved surface, such as a pipe, the bellows structure of the bellows-like module band is deformed according to the curved shape of the heat source surface, and the top portion or the bottom portion of the bellows-like module band can be appropriately installed. so as to come into contact with the heat source.

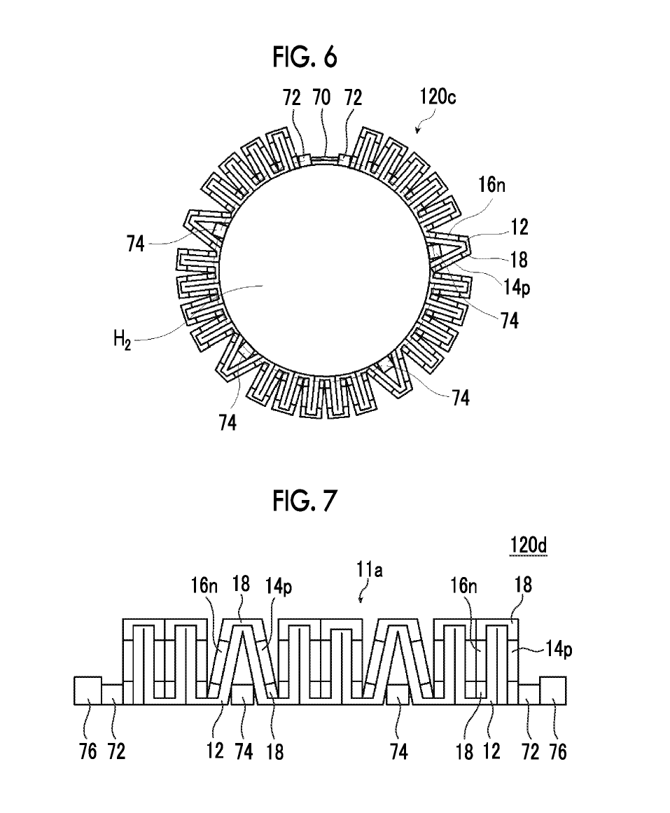

For example, as shown in FIG. 6, in a case where the thermoelectric conversion device 120c shown in FIG. 5 is arranged on the surface of a cylindrical pipe H₂ (heat source), the bellows structure of the bellows-like module band 11a is deformed along the curved shape of the surface of the pipe H₂ such that the bottom portion b of the bellows-like module band 11a comes into contact with the surface of the pipe H₂ (heat source) and the both end portions of the wire 70 are connected to each other and fixed so that the thermoelectric conversion device 120c can be installed while being held in a shape along the curved shape of the surface of the pipe H₂.

At this time, since the heat transfer member 74 is arranged between at least some of the plate-like portions 13, even in a case where the bellow structure of the bellows-like module band 11a is deformed along the curved shape of the surface of the pipe H₂, the plate-like portions 13 (thermoelectric conversion modules) do not easily fall down and the plate-like portions 13 can be more suitably held in a state of being substantially perpendicular to the installation surface.

In addition, the thermoelectric conversion device of the present invention may have a configuration in which magnets are arranged to sandwich the thermoelectric conversion module band therebetween in the direction in which the plurality of plate-like portions are laminated. That is, magnets may be provided on both end surface sides of the bellows-like module band.

For example, a thermoelectric conversion device 120d shown in FIG. 7 has magnets 76 arranged on the surface of the end portion fixing member 72 opposite to the bellows-like module band 11a. The thermoelectric conversion device 120d shown in FIG. 7 has the same configuration as the thermoelectric conversion device 120c shown in FIG. 5 except that the magnets 76 are provided. Thus, the same symbols are attached to the same constitutional elements and the detailed descriptions thereof are omitted.

The magnet 76 may be fixed to the end portion fixing member 72 with an adhesive or the like and in a case where the end portion fixing member 72 is formed of a magnetic body of iron or the like or the magnet 76 may be fixed to the end portion fixing member 72 by the magnetic force of the magnet 76. Using a magnet 76 having a through hole, a wire 70 and the magnet 76 may be fixed by inserting the wire 70 into the through hole with an adhesive or the like.

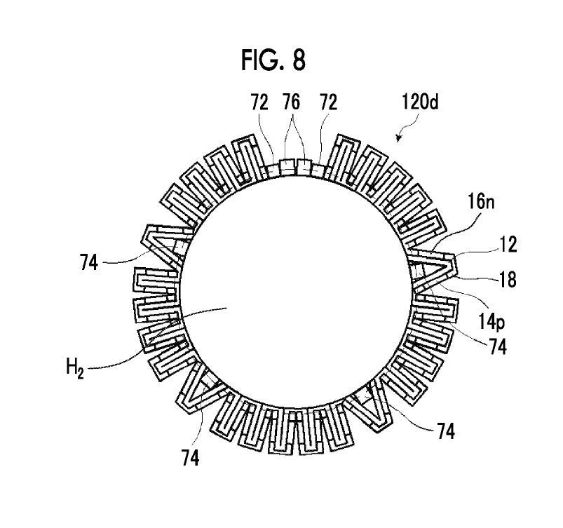

In this manner, due to the configuration in which the magnets 76 are provided, in a case where the thermoelectric conversion device 120d is arranged on the surface of a cylindrical pipe H₂ (heat source) as shown in FIG. 8, the bellows structure of the bellows-like module band 11a is deformed along the curved shape of the surface of the pipe H₂ such that the bottom portion b of the bellows-like module band 11a comes into contact with the surface of the pipe H₂ (heat source) and the magnet 76 and the pipe H₂ are fixed by a magnetic force so that the thermoelectric conversion device 120d can he installed while being held in a shape along the curved shape of the surface of the pipe H₂. In addition, since the thermoelectric conversion device is fixed to the pipe H₂ by the magnetic force of the magnet 76, the thermoelectric conversion device can be easily attached to or detached from the pipe. Further, since the thermoelectric conversion device is fixed to the pipe by the magnetic force of the magnet 76, the thermoelectric conversion device can he easily installed on pipes having different diameters according to the respective diameters.

In a case where the material for forming the pipe H₂ is a non-magnetic body such as resin, the magnets 76 may be fixed by the magnetic force.

Here, in the example shown in FIG. 1, the configuration in which two through holes 22 are formed in each of the plate-like portions 13 and two wires 70 inserted into each of the two through holes 22 are provided is adopted. However, there is no limitation thereto. A configuration in which one through hole 22 is formed on each of the plate-like portions 13 and one wire 70 inserted into the through hole 22 is provided may be adopted. Alternatively, a configuration in which three or more through holes 22 are formed in each of the plate-like portions 13 and three wires 70 inserted into each of the through holes 22 are provided may be adopted.

In addition, the position where the through hole 22 is formed in the plate-like portion 13 is in the region in which the thermoelectric conversion layer and the wiring member 18 are not arranged. However, there is no limitation thereto. The through hole 22 may be formed at the position where the thermoelectric conversion layer is arranged or at the position where the wiring member 18 is arranged.

In the example shown in FIG. 1, the configuration in which the through hole 22 is formed on the bottom portion b (valley fold portion) side of the plate-like portion 13 is adopted. However, there is no limitation thereto. The through hole may be formed in a region on the top portion a (mountain fold portion) side or may be formed in a region at a substantially center portion between the top portion a and the bottom portion b. As shown in the examples of FIGS. 6 and 8, from the viewpoint that the thermoelectric conversion device is easily installed on the curved surface of the pipe or the like in a case of installation, it is preferable to adopt a configuration in which the through hole 22 is formed in a region on the side of the plate-like portion 13 in contact with the heat source (the bottom b side in the drawing) and the wire 70 is inserted thereinto.

Herein, in the examples shown in FIGS. 6 and 8, the configuration in which the bottom portion b side of the bellows-like module band 11a is arranged to be in contact with the heat source is adopted. However, there is no limitation thereto. A configuration in which the top portion a side of the bellows-like module band 11a is arranged to be in contact with the heat source may be adopted.

In the example shown in FIG. 7, the configuration in which the end portion fixing member 72 and the magnet 76 are provided as separated members is adopted. However, there is no limitation thereto. A configuration in which the end portion fixing member 72 and the magnet 76 are integrally provided may be adopted. That is, a magnet may he used as the material forming the end portion fixing member 72 or a part of the end portion fixing member 72 may be formed of a magnet.

In a case of a small thickness (the thickness in the lamination direction of the plate-like portion 13) in a case of closing the bellows-like module band 11a, a configuration in which the plurality of plate-like portions 13 are pressed in the lamination direction thereof using a magnet as the end portion fixing member 72 with the magnetic force of the magnet may be provided.

In the example shown in FIG. 1, the configuration in which the bellows-like module band 11a has the P-type thermoelectric conversion layer 14p and the N-type thermoelectric conversion layer 16n as the thermoelectric conversion layers is adopted. However, there is no limitation thereto. Only the P-type thermoelectric conversion layer 14p may be provided or only the N-type thermoelectric conversion layer 16n may be provided.

For example, in a case of using only the P-type thermoelectric conversion layer 14p, as a configuration in which the thermoelectric conversion layer is arranged only at the position where the P-type thermoelectric conversion layer 14p is arranged in the example shown in FIG. 1, a configuration in which the respective P-type thermoelectric conversion layer 14p are connected to each other in series may be adopted. Alternatively, as a configuration in which the P-type thermoelectric conversion layers are arranged at the positions where the P-type thermoelectric conversion layer 14p and the N-type thermoelectric conversion layer 16n are arranged in the example shown in FIG. 1, a configuration in which the respective P-type thermoelectric conversion layers 14p are connected to each other in series along the direction in which the electromotive force of each P-type thermoelectric conversion layer 14p is generated may be adopted.

Next, each constitutional elements of the thermoelectric conversion device of the present invention will be described.

The insulating substrate 12 has the plurality of thermoelectric conversion elements (the thermoelectric conversion layer and the wiring member 18) formed thereon to constitute the thermoelectric conversion module and functions as a support for the thermoelectric conversion elements. Since voltage is generated in the thermoelectric conversion module, the insulating substrate 12 is required to have electrically insulating properties, and a substrate having electrically insulating properties is used for the insulating substrate 12. The electrically insulating properties required for the insulating substrate 12 are to prevent a short circuit or the like due to the voltage generated in the thermoelectric conversion module from occurring, Regarding the insulating substrate 12, a substrate is appropriately selected according to the voltage generated in the thermoelectric, conversion module.

For example, the insulating substrate 12 is a plastic substrate. For the plastic substrate, a plastic film can be used.

Specific examples of the plastic film that can be used include films or sheet-like materials or plate-like materials of polyester resins such as polyethylene terephthalate, polyethylene isophthalate, polyethylene naphthalate, polybutylene terephthalate, poly(l,4-cyclohexylene dimethylene terephthalate), and polyethylene-2,6-naphthalenedicarboxylate, resins such as polyimide, polycarbonate, polypropylene, polyethersulfone, cycloolefin polymer, and polyether ether ketone (PEEK), triacetyl cellulose (TAC), glass epoxy, and liquid crystal polyester.

Among these, from the viewpoint of thermal conductivity, heat resistance, solvent resistance, ease of availability, and economy, films of polyimide, polyethylene terephthalate, polyethylene naphthalate, and the like are suitably used for the insulating substrate 12.

The through hole 22 formed by penetrating the insulating substrate 12 can be formed by numerically controlled (NC) drilling, laser processing, chemical etching, plasma etching or the like.

In addition, the size, the shape, and the arrangement of the through hole are not limited and may be appropriately selected according to the size and the shape of the inserted linear member or the like.

Next, the thermoelectric conversion layer will be described.

The thermoelectric conversion layer can adopt all various configurations using known thermoelectric conversion materials. Accordingly, the thermoelectric conversion layer may be formed using an organic thermoelectric conversion material or an inorganic thermoelectric conversion material. Further, the thermoelectric conversion layer may be formed of a P-type material or an N-type material, or may be formed of both a P-type material and an N-type material.

Hereinafter, the P-type thermoelectric conversion layer and the N-type thermoelectric conversion layer will be described.

As the thermoelectric conversion material constituting the P-type thermoelectric conversion layer and the N-type thermoelectric conversion layer, for example, nickel or a nickel alloy may be used.

As the nickel alloy, various nickel alloys that generate power by causing a temperature difference can be used. Specific examples thereof include nickel alloys mixed with one or two or more of vanadium, chromium, silicon, aluminum, titanium, molybdenum, manganese, zinc, tin, copper, cobalt, iron, magnesium, and zirconium.

In a case where nickel or a nickel alloy is used for the P-type thermoelectric conversion layer and the N-type thermoelectric conversion layer, the nickel content in the P-type thermoelectric conversion layer and the N-type thermoelectric conversion layer is preferably 90% by atom or more and more preferably 95% by atom or more, and the thermoelectric conversion layers are particularly preferably formed of nickel. The P-type thermoelectric conversion layer and the N-type thermoelectric conversion layer formed of nickel include inevitable impurities.

As the thermoelectric conversion material for the P-type thermoelectric conversion layer, chromel having Ni and Cr as main components is typically used. As the thermoelectric conversion material for the N-type thermoelectric conversion layer, constantan having Cu and Ni as main components is typically used.

In addition, in a case where nickel or a nickel alloy is used for the P-type thermoelectric conversion layer and the N-type thermoelectric conversion layer and also nickel or a nickel alloy is used for an electrode, the P-type thermoelectric conversion layer, the e thermoelectric conversion layer, and the wiring member may be integrally formed.

As other thermoelectric conversion materials for the P-type thermoelectric conversion layer and the N-type thermoelectric conversion layer, for example, the following materials may be used. Incidentally, the components in parentheses indicate the material composition. Examples of the materials include BiTe-based materials (BiTe, SbTe, BiSe and compounds thereof), PbTe-based materials (PbTe, SnTe, AgSbTe, GeTe and compounds thereof), Si-Ge-based materials (Si, Ge, SiGe), silicide-based materials (FeSi, MnSi, CrSi), skutterudite-based materials (compounds represented by MX₃ or RM₄X₁₂, where M equals Co, Rh, or Ir, X equals As, P, or Sb, and R equals La, Yb, or Ce), transition metal oxides (NaCoO, CaCoO, ZnInO, SrTiO, BiSrCoO, PbSrCoO, CaBiCoO, BaBiCoO), zinc antimony based compounds (ZnSb), boron compounds (CeB, BaB, SrB, CaB, MgB, VB, NiB, CuB, LiB), cluster solids (B cluster, Si cluster, C cluster, AlRe, AlReSi), and zinc oxides (ZnO). In addition, the film formation method is arbitrary and a film formation method such as a sputtering method, a vapor deposition method, a chemical vapor deposition (CVD) method, a plating method, or an aerosol deposition method can be used.

For the thermoelectric conversion material used for the P-type thermoelectric conversion layer and the N-type thermoelectric conversion layer, materials that can form a film by coating or printing and can he made into paste can he used. Various configurations using known thermoelectric conversion materials basically formed of an organic material can be used.

Specific examples of the thermoelectric conversion material from which the P-type thermoelectric conversion layer and the N-type thermoelectric conversion layer as described above can be obtained include an organic thermoelectric conversion material such as a conductive polymer or a conductive nanocarbon material may be used.

Examples of the conductive polymer include a polymer compound having a conjugated molecular structure (conjugated polymer). Specific examples thereof include known π-conjugated polymers such as polyaniline, polyphenylene vinylene, polypyrrole, polythiophene, polyfluorene, acetylene, and polyphenylene. Particularly, polydioxythiophene can be suitably used.

Specific examples of the conductive nanocarbon material include carbon nanotubes (hereinafter, also referred to as CNTs), carbon nanofiber, graphite, graphene, and carbon nanoparticles. These may be used singly or in combination of two or more thereof. Among these, from the viewpoint of further improving thermoelectric conversion properties, CNT is preferably used.

CNT is categorized into single layer CNT of one carbon film (graphene sheet) wound in the form of a cylinder, double layer CNT of two graphene sheets wound in the form of concentric circles, and multilayer CNT of a plurality of graphene sheets wound in the form of concentric circles. In the present invention, each of the single layer CNT, the double layer CNT, and the multilayer CNT may be used singly, or two or more thereof may be used in combination. Particularly, the single layer CNT and the double layer CNT excellent in conductivity and semiconductor characteristics are preferably used, and the single layer CNT is more preferably used.

The single layer CNT may be semiconductive or metallic. Furthermore, semiconductive CNT and metallic CNT may be used in combination. In a case where both of the semiconductive CNT and the metallic CNT are used, a content ratio between the CNTs in a composition can be appropriately adjusted according to the use of the composition. In addition, CNT may contain a metal or the like, and CNT containing fullerene molecules and the like may be used.

An average length of CNT is not particularly limited and can be appropriately selected according to the use of the composition. Specifically, from the viewpoint of ease of manufacturing, film formability, conductivity, and the like, the average length of CNT is preferably 0.01 μm to 2,000 μm, more preferably 0.1 μm to 1,000 μm, and particularly preferably 1 μm to 1,000 μm, though the average length also depends on an inter-electrode distance.

A diameter of CNT is not particularly limited, From the viewpoint of durability, transparency, film formability, conductivity, and the like, the diameter is preferably 0.4 nm to 100 nm, more preferably 50 nm or less, and particularly preferably 15 nm or less.

Particularly, in a ease where the single layer CNT is used, the diameter is preferably 0.5 μm to 2.2 nm, more preferably 1.0 μm to 2.2 nm, and particularly preferably 1.5 μm to 2.0 nm.

The CNT contained in the obtained conductive composition contains defective CNT in some cases. Because the defectiveness of the CNT deteriorates the conductivity of the composition, it is preferable to reduce the amount of the defective CNT. The amount of defectiveness of the CNT in the composition can be estimated by a G/D ratio between a G band and a D band in a Raman spectrum. In a case where the G/D ratio is high, the composition can be assumed to be a CNT material with a small amount of defectiveness. The G/D ratio of the composition is preferably 10 or higher and more preferably 30 or higher.

In addition, modified or treated CNT can also be used. Examples of the modification or treatment method include a method of incorporating a ferrocene derivative or nitrogen-substituted fullerene (azafullerene) into CNT, a method of doping CNT with an alkali metal (potassium or the like) or a metallic element (indium or the like) by an ion doping method, and a method of heating CNT in a vacuum.

In a case where CNT is used, in addition to the single layer CNT or the multilayer CNT, nanocarbons such as carbon nanohorns, carbon nanocoils, carbon nanobeads, graphite, graphene, amorphous carbon, and the like may be contained in the composition.

In a case where CNT is used in the P-type thermoelectric conversion layer or the N-type thermoelectric conversion layer, it is preferable that CNT includes a P-type dopant or an N-type dopant.

(P-Type Dopant)

Examples of the P-type dopant include halogen (iodine, bromine, or the like), Lewis acid (PF₅, AsF₅, or the like), protonic acid (hydrochloric acid, sulfuric acid, or the like), transition metal halide (FeCl₃, SnCl₄, or the like), a metal oxide (molybdenum oxide, vanadium oxide, or the like), and an organic electron-accepting material. Examples of the organic electron-accepting material suitably include a tetracyanoquinodimethane (TCNQ) derivative such as 2,3,5,6-tetrafluoro-7,7,8,8-tetracyanoquinodimethane, 2,5-dimethyl-7,7,8,8-tetracyanoquinodimethane, 2-fluoro-7,7,8,8-tetracyanoquinodimethane, or 2,5-difluoro-7,7,8,8-tetracyanoquinodimethane, a benzoquinone derivative such as 2,3-dichloro-5,6-dicyano-p-benzoquinone or tetrafluoro-1,4-benzoquinone, 5,8H-5,8-bis(dicyanomethylene)quinoxaline, dipyrazino[2,3-f:2′,3′-h]quinoxaline-2,3,6,7,10,11-hexacarbonitrile, and the like.

Among these, from the viewpoint of the stability of the materials, the compatibility with CNT, and the like, organic electron-accepting materials such as a tetracyanoquinodimethane (TCNQ) derivative or a benzoquinone derivative is suitably exemplified.

The P-type dopant and the N-type dopant may be used singly or in combination of two or more thereof.

(N-Type Dopant)

As the N-type dopant, known material such as (1) alkali metals such as sodium and potassium, (2) phosphines such as triphenylphosphine and ethylenebis(diphenylphosphine), (3) polymers such as polyvinyl pyrrolidone and polyethylene imine, and the like can be used. In addition, for examples, polyethylene glycol type higher alcohol ethylene oxide adducts, ethylene oxide adducts of phenol, naphthol or the like, fatty acid ethylene oxide adducts, polyhydric alcohol fatty acid ester ethylene oxide adducts, higher alkylamine ethylene oxide adducts, fatty acid amide ethylene oxide adducts, ethylene oxide adducts of fat, polypropylene glycol ethylene oxide adducts, dimethylsiloxane-ethylene oxide block copolymers, diinethylsiloxane-(propylene oxide-ethylene oxide) block copolymers, fatty acid esters of polyhydric alcohol type glycerol, fatty acid esters of pentaerythritol, fatty acid esters of sorbitol and sorbitan, fatty acid esters of sucrose, alkyl ethers of polyhydric alcohols and fatty acid amides of alkanolamines. Further, acetylene glycol based and acetylene alcohol-based oxyethylene adducts, and fluorine-based and silicon-based surfactants can be also used,

As the thermoelectric conversion layer, the thermoelectric conversion layer obtained by dispersing the aforementioned thermoelectric conversion material in a resin material (binder) is suitably used.

Among these, the thermoelectric conversion layer obtained by dispersing a conductive nanocarbon material in a resin material is more suitably exemplified. Especially, the thermoelectric conversion layer obtained by dispersing CNT in a resin material is particularly suitably exemplified because this makes it possible to obtain high conductivity and the like.

As the resin material, various known nonconductive resin materials (polymers)can be used.

Specifically, it is possible to use various known resin materials such as a vinyl compound, a (meth)acrylate compound, a carbonate compound, an ester compound, an epoxy compound, a siloxane compound, and gelatin.

More specifically, examples of the vinyl compound include polystyrene, polyvinyl naphthalene, polyvinyl acetate, polyvinyl phenol, and polyvinyl butyral. Examples of the (meth)acrylate compound include polymethyl (meth)acrylate, polyethyl (meth)acrylate, polyphenoxy(poly)ethylene glycol (meth)acrylate, and polybenzyl (meth)acrylate. Examples of the carbonate compound include bisphenol Z-type polycarbonate, and bisphenol C-type polycarbonate. Examples of the ester compound include amorphous polyester.

Polystyrene, polyvinyl butyral, a (meth)acrylate compound, a carbonate compound, and an ester compound are preferable, and polyvinyl butyral, polyphenoxy(poly)ethylene glycol (meth)acrylate, polybenzyl (meth)acrylate, arid amorphous polyester are more preferable.

In the thermoelectric conversion layer obtained by dispersing a thermoelectric conversion material in a resin material, a quantitative ratio between the resin material and the thermoelectric conversion material may be appropriately set according to the material used, the thermoelectric conversion efficiency required, the viscosity or solid content concentration of a solution exerting an influence on printing, and the like.

As another configuration of the thermoelectric conversion layer in the thermoelectric conversion element, a thermoelectric conversion layer mainly constituted of CNT and a surfactant is also suitably used.

By constituting the thermoelectric conversion layer of CNT and a surfactant, the thermoelectric conversion layer can be formed using a coating composition to which a surfactant is added. Therefore, the thermoelectric conversion layer can be formed using a coating composition in which CNT is smoothly dispersed. As a result, by a thermoelectric conversion layer including a large amount of long and less defective CNT, excellent thermoelectric conversion performance is obtained.

As the surfactant, known surfactants can be used as long as the surfactants function to disperse CNT. More specifically, various surfactants can be used as the surfactant as long as surfactants dissolve in water, a polar solvent, or a mixture of water and a polar solvent and have a group adsorbing CNT.

Accordingly, the surfactant may be ionic or nonionic. Furthermore, the ionic surfactant may be any of cationic, anionic, and amphoteric surfactants.

Examples of the anionic surfactant include an aromatic sulfonic acid-based surfactant such as alkylbenzene sulfonate like dodecylbenzene sulfonate or dodecylphenyl ether sulfonate, a monosoap-based anionic surfactant, an ether sulfate-based surfactant, a phosphate-based surfactant and a carboxylic acid-based surfactant such as sodium deoxycholate or sodium cholate, and a water-soluble polymer such as carboxymethyl cellulose and a salt thereof (sodium salt, ammonium salt, or the like), a polystyrene sulfonate ammonium salt, or a polystyrene sulfonate sodium salt.

Examples of the cationic surfactant include an alkylamine salt and a quaternary ammonium salt. Examples of the amphoteric surfactant include an alkyl betaine-based surfactant, and an amine oxide-based surfactant.

Further, examples of the nonionic surfactant include a sugar ester-based surfactant such as sorbitan fatty acid ester, a fatty acid ester-based surfactant such as polyoxyethylene resin acid ester, and an ether-based surfactant such as polyoxyethylene alkyl ether.

Among these, an ionic surfactant is preferably used, and cholate or deoxycholate is particularly suitably used.

In the thermoelectric conversion layer, a mass ratio of surfactant/CNT is preferably 5 or less, and more preferably 3 or less.

It is preferable that the mass ratio of surfactant/CNT is 5 or less from the viewpoint that a higher thermoelectric conversion performance or the like is obtained.

If necessary, the thermoelectric conversion layer formed of an organic material may contain an inorganic material such as SiO₂, TiO₂, Al₂O₃, or ZrO₂.

In a case where the thermoelectric conversion layer contains an inorganic material, a content of the inorganic material is preferably 20% by mass or less, and more preferably 10% by mass or less.

In the thermoelectric conversion element, a thickness of the thermoelectric conversion layer, a size of the thermoelectric conversion layer in a plane direction, a proportion of an area of the thermoelectric conversion layer with respect to the insulating substrate along the plane direction, and the like may be appropriately set according to the material forming the thermoelectric conversion layer, the size of the thermoelectric conversion element, and the like.

Next, a method of forming the thermoelectric conversion layer will be described.

The prepared coating composition which becomes the thermoelectric conversion layer is patterned and applied according to a thermoelectric conversion layer to be formed. The application of the coating composition may be performed by a known method such as a method using a mask or a printing method.

After the coating composition is applied, the coating composition is dried by a method according to the resin material, thereby forming the thermoelectric conversion layer. If necessary, after the coating composition is dried, the coating composition (resin material) may be cured by being irradiated with ultraviolet rays or the like.

Alternatively, the prepared coating composition which becomes the thermoelectric conversion layer is applied to the entire surface of the insulating substrate and dried, and then the thermoelectric conversion layer may be formed as a pattern by etching or the like.

Next, in a case where the thermoelectric conversion layer is formed by a coating composition prepared such a manner that CNT and a surfactant are added to water and dispersed (dissolved), it is preferable to form the thermoelectric conversion layer by forming the thermoelectric conversion layer with the coating composition, then immersing the thermoelectric conversion layer in a solvent for dissolving the surfactant or washing the thermoelectric conversion layer with a solvent for dissolving the surfactant, and drying the thermoelectric conversion layer. Thus, it is possible to form the thermoelectric conversion layer having a very small mass ratio of surfactant/CNT by removing the surfactant from the thermoelectric conversion layer and more preferably not containing the surfactant. The thermoelectric conversion layer is preferably formed as a pattern by printing.

As the printing method, various known printing methods such as screen printing and metal mask printing can be used. In a case where the thermoelectric conversion layer is formed as a pattern by using a coating composition containing CNT, it is more preferable to use metal mask printing. The printing conditions may be appropriately set according to the physical properties (solid content concentration, viscosity, and viscoelastic properties) of the coating composition used, the opening size of a printing plate, the number of openings, the opening shape, a printing area, and the like. Specifically, an attack angle of a squeegee is preferably 50° or less, more preferably 40° or less, and particularly preferably 30° or less. As the squeegee, it is possible to use an obliquely polished squeegee, a sword squeegee, a square squeegee, a flat squeegee, a metal squeegee, and the like. A clearance is preferably 0.1 mm to 3.0 mm, and more preferably 0.5 mm to 2.0 mm. The printing can be performed at a printing pressure of 0.1 MPa to 0.5 MPa in a squeegee indentation amount of 0.1 mm to 3 mm. By performing printing under such conditions, a CNT-containing thermoelectric conversion layer pattern having a film thickness of 1 μm or more can be suitably formed.

The thickness of the thermoelectric conversion layer, the size of the thermoelectric conversion layer in the plane direction, and the like may be appropriately set according to the material forming the thermoelectric conversion layer, the size of the thermoelectric conversion element, and the like.

The wiring members 18 are formed at both ends of the pattern of the thermoelectric conversion layer in the temperature difference direction and electrically connect the plurality of thermoelectric conversion layers. The wiring member 18 is not particularly limited as long as the wiring member 18 is formed of a conductive material and any material may be used. As the material constituting the wiring member 18, metal materials such as Al, Cu, Ag, Au, Pt, Cr, Ni, and solder are preferable, From the viewpoint of conductivity and being capable of performing soldering at a low temperature or the like, the wiring member is preferably constituted of copper. In addition, the wiring member 18 may be constituted of a copper alloy.

The thickness, the size, and the like of the wiring member 18 may be appropriately set according to the thickness, the size, the shape, and the arrangement pattern of the thermoelectric conversion layer.

The linear member (wire) 70 is preferably a linear member having a flexibility, and various materials can be used. Specifically, a thread (string), a metal wire such as a wire, a metal wire covered by an insulating material, and the like may be used.

The diameter, the length, the cross section shape, and the like of the linear member 70 are not limited and may be appropriately set according to the size and the shape of the through hole, or the size and the number of thermoelectric conversion modules, and the like.

The end portion fixing member 72 is a member which presses the bellows-like module band 11a in the lamination direction of the plate-like portion 13.

The material forming the end portion fixing member 72 is not limited and various metals such as aluminum, iron, and stainless steel, or various resin materials can be used. As described above, a magnet may be used as the end portion fixing member 72.

The shape of the end portion fixing member 72 is not limited and various shapes such a square column shape like a cubic shape or a rectangular parallelepiped shape, a triangular column shape, a polygonal column shape, and a circular column shape can be used.

In addition, the size of the end portion fixing member 72 or the like is not limited and may be appropriately set according to the size of the bellows-like module band 11a, the diameter of the linear member 70, and the like. For example, the width of the end portion fixing member 72 may be substantially the same as the width of the bellows-like module band 11a.

In the end portion fixing member 72, a through hole is formed at a position corresponding to the through hole 22 formed on the plate-like portion 13 of the bellows-like module band 11a. Accordingly, as shown in the example in FIG. 1, in a case where the bellows-like module band 11a has two through holes 22 in the plate-like portion 13 and the width of the end portion fixing member 72 is substantially the same as the width of the bellows-like module band 11a, the end portion fixing member 72 has two through holes on both end portion sides in the width direction.

There is no limitation to a configuration in which one end portion fixing member 72 is arranged on one end portion side of the bellows-like module band 11 a and two or more through holes are formed in one end portion fixing member 72, and two or more end portion fixing members may be provided according to the number of through holes 22 of the plate-like portion 13.

The heat transfer member 74 is arranged between the plate-like portions 13 of the bellows-like module band 11a and is formed of a material having high thermal conductivity.

The thermal conductivity of the heat transfer member 74 is preferably 10 W/mK or higher. In a case where the thermal conductivity of the heat transfer member 74 is 10 W/mK or higher, a large amount of heat can be supplied to the thermoelectric conversion module from a high temperature side. In addition, a large amount of heat can be discharged to a low temperature side and this case is preferable.

On the other hand, in a case where the thermal conductivity is lower than 10 W/mK, the supply of the amount of heat and the discharge of the amount of heat described above are not enough.

The value of the thermal conductivity of the heat transfer portion 74 described above is a published value such as value of the thermal conductivity described in Handbook of Physical Properties or a value of thermal conductivity released by manufacturers.

Specifically, as the material forming the heat transfer member 74, various metals such as aluminum, iron, and stainless steel are suitably used.

The size, the cross section shape, and the like of the heat transfer member 74 are not limited and may be appropriately set according to the size, the shape, and the like of the bellows-like module band 11a.

The magnet 76 is used for fixing the thermoelectric conversion device. As the magnet 76, a known permanent magnet such as a ferrite magnet or an Alnico magnet can be used.

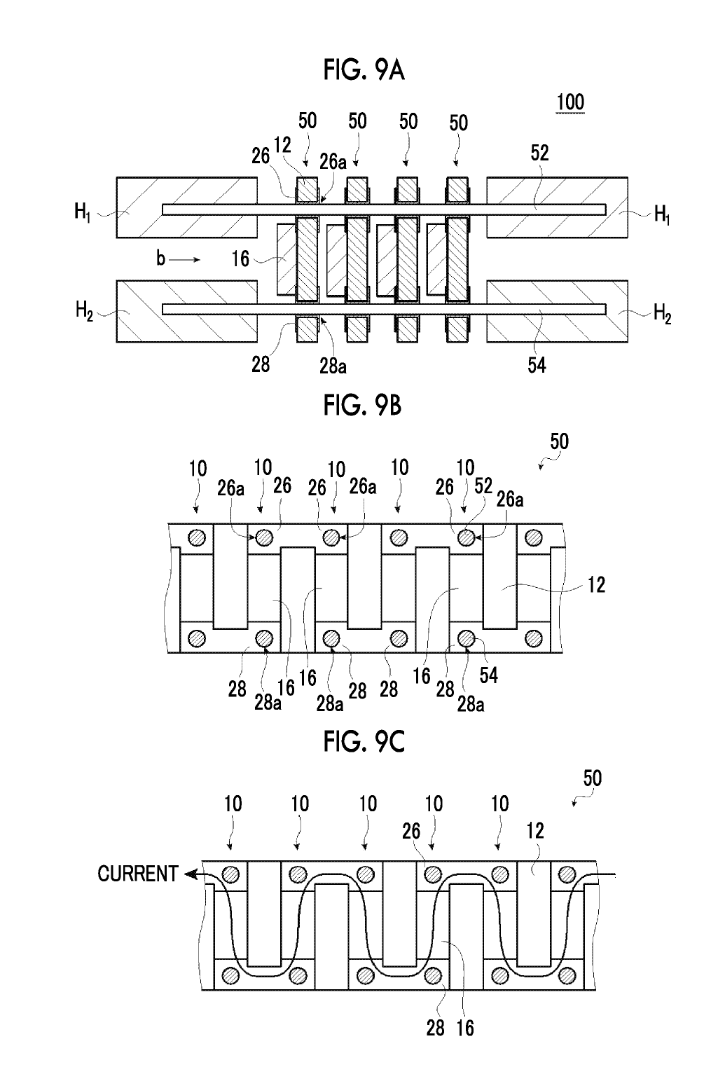

FIG. 9A is a cross-sectional view conceptually showing an example of the thermoelectric conversion device, and FIG. 9B is an enlarged view showing a portion as FIG. 9A is seen from a direction b.

A thermoelectric conversion device 100 shown in FIGS. 9A and 9B includes a plurality of thermoelectric conversion modules 50 having an insulating substrate 12, a thermoelectric conversion layer 16, a wiring member 26, and a wiring member 28, and a rod-like member 52 and a rod-like member 54 which penetrate the plurality of thermoelectric conversion modules 50.

In addition, both end portions of the rod-like member 52 come into contact with a heat source H₁ and both end portions of the rod-like member 54 come into contact with a heat source H₂. One of the heat sources H₁ and H₂ is a low temperature heat source and the other is a high temperature heat source. Hereinafter, as an example, a case where the heat source H₁ is a low temperature heat source and the heat source H₂ is a high temperature heat source will be described.

The rod-like member 52 and the rod-like member 54 are linear members in the present invention.

As shown in the drawing, the thermoelectric conversion module 50 has a rectangular plate-like insulating substrate 12, a plurality of thermoelectric conversion layers 16 arranged at intervals set in advance in an extending direction (first direction) of the insulating substrate 12, and a wiring member 26 and a wiring member 28 arranged for each thermoelectric conversion layer to sandwich the thermoelectric conversion layer therebetween in a transverse direction (second direction) of the insulating substrate 12 orthogonal to the first direction.

One thermoelectric conversion layer 16 and the wiring member 26 and the wiring member 28 which sandwich the thermoelectric conversion layer 16 form a thermoelectric conversion element 10. That is, the thermoelectric conversion module 50 has a plurality of thermoelectric conversion elements 10 arranged on the insulating substrate 12 at predetermined intervals in the first direction.

In the following description, the second direction is also referred to as a vertical direction of the thermoelectric conversion module, and the first direction is also referred to as a horizontal direction of the thermoelectric conversion module. In addition, the wiring member 26 refers to a wiring member disposed on an upper side in the vertical direction of the thermoelectric conversion layer 16 and the wiring member 28 refers to a wiring member disposed on a lower side of the thermoelectric conversion layer 16.

In addition, the wiring member 26 and the wiring member 28 have the same basic configuration except that the arrangement is different. Thus, in a case where there is no need to distinguish the wiring member 26 and the wiring member 28, the wiring members are collectively referred to as the wiring member. As the materials forming the wiring member 26 and the wiring member 28, the same materials used in the formation of the wiring member 18 can be used. In addition, the materials forming the wiring member 26 and the wiring member 28 may be the same as or different from each other.

Similarly, the rod-like member 52 and the rod-like member 54 basically have the same configuration except that the arrangement is different. Thus, in a case where there is no need to distinguish the rod-like member 52 and rod-like member 54, the members are collectively referred to as the rod-like member.

In addition, the wiring member 26 is electrically connected to the wiring member 26 corresponding to one thermoelectric conversion layer 16 adjacent to the corresponding thermoelectric conversion layer 16, and the wiring member 28 is electrically connected to the wiring member 28 corresponding to one thermoelectric conversion layer 16 adjacent to the corresponding thermoelectric conversion layer 16. That is, the wiring members 26 and the wiring members 28 of adjacent thermoelectric conversion elements 10 are connected to each other.

Thus, as shown in FIG. 9C, the plurality of thermoelectric conversion elements 10 are connected to each other in series and a current flows in a direction indicated by an arrow in the drawing.

Specifically, as shown in FIG. 9C, it is preferable that the plurality of thermoelectric conversion layers 16 arranged on the insulating substrate 12 are connected to each other in series by alternately arranging the thermoelectric conversion layer which generates power such that a current flows from the wiring member 28 side (high temperature heat source H₂ side) to the wiring member 26 side (low temperature heat source H₁ side) and the thermoelectric conversion layer which generates power such that a current flow from the wiring member 26 side (low temperature heat source H₁ side) to the wiring member 28 side (high temperature heat source H₂ side).

That is, it is preferable that a thermoelectric conversion layer (P-type thermoelectric conversion layer) formed of a P-type material, and a thermoelectric conversion layer (N-type thermoelectric conversion layer) formed of an N-type material, which mutually generate power in different directions with respect to the provided temperature difference, are alternately arranged.

Here, each thermoelectric conversion module 50 has a through bole 26a which penetrates the wiring member 26 and the insulating substrate 12, and a through hole 28a which penetrates the wiring member 28 and the insulating substrate 12, respectively. The rod-like member 52 is inserted into the through hole 26a and the rod-like member 54 is inserted into the through hole 28a.

In addition, the plurality of thermoelectric conversion modules 50 are arranged (laminated) in a direction perpendicular to the principal surface of the thermoelectric conversion module, the rod-like member 52 transects the plurality of thermoelectric conversion modules 50 and is inserted into the through hole 26a of each thermoelectric conversion module 50, and the rod-like member 54 transects the plurality of thermoelectric conversion modules 50 and is inserted into the through hole 28a of each thermoelectric conversion module 50.

Here, as described above, the both end portions of the rod-like member 52 come into contact with the low temperature heat source H₁ and the both end portions of the rod-like member 54 come into contact with the high temperature heat source H₂. Therefore, the heat of the high temperature heat source H₂ is transferred to each wiring member 28 through the rod-like member 54 to increase the temperature of the wiring member 28, and each wiring member 26 connected to the low temperature heat source H₁ through the rod-like member 52 is cooled to decrease the temperature of the wiring member 26. Thus, a temperature difference is generated between the wiring member 26 and the wiring member 28. Therefore, the thermoelectric conversion layer 16 arranged between the wiring member 26 and the wiring member 28 converts heat energy to electrical energy, that is, generates power according to the temperature difference. The electrical energy that the thermoelectric conversion layer 16 generates is taken out through the wiring member 26 and the wiring member 28 functioning as electrodes.

A thermoelectric conversion device of the related art in which a large number of π-type thermoelectric conversion elements are connected to each other has a problem of having a complicated manufacturing step and requiring much time and labor. In addition, there is a problem that an influence of thermal strain or a change in thermal strain due to a difference in thermal expansion coefficient of each member is repeatedly generated to cause a fatigue phenomenon at the interface, thereby resulting in performance deterioration.

As a thermoelectric conversion device which is easily manufactured and less likely to have a problem of an influence of thermal strain due to a difference in thermal expansion coefficient of each member or the like, a thermoelectric conversion module formed such that a thermoelectric conversion layer and a wiring member are arranged in a plane direction of a substrate and a temperature difference is generated in the plane direction to convert heat energy to electrical energy is disclosed.

In such a thermoelectric conversion, module in which a temperature difference is generated in the plane direction of the substrate, it is necessary that the end surface of the thin substrate is brought into contact with a heat source such that the substrate is erected for the heat source. In addition, in order to achieve high output density of the thermoelectric conversion device, the use of the plurality of thermoelectric conversion modules being overlapped is proposed.

Here, in the thermoelectric conversion module, in order to provide a temperature difference in a predetermined direction, a material having a low thermal conductivity is used for the insulating substrate.

Therefore, since in the thermoelectric conversion device formed by overlapping the plurality of thermoelectric conversion modules, the insulating substrates formed by a material having a low thermal conductivity, such as polyimide, are overlapped, heat is not easily transferred to the thermoelectric conversion module positioned in the inner side in a case of overlapping the substrates, and a temperature difference is not easily generated. Thus, there is a problem of decreasing the power generation amount of the thermoelectric conversion device.

In addition, in a case where a space between the thermoelectric conversion modules is filled with a filler to secure the self-supporting properties of the overlapped thermoelectric conversion modules, since heat insulating properties are decreased, a temperature difference is not easily generated in the thermoelectric conversion module and thus there is a problem of decreasing the power generation amount.

In contrast, the thermoelectric conversion device 100 has a configuration in which each thermoelectric conversion module 50 respectively has the through hole 26a which penetrates the wiring member 26 and the insulating substrate 12, and the through hole 28a which penetrates the wiring member 28 and the insulating substrate 12, the rod-like member 52 transects the plurality of thermoelectric conversion modules 50 and is inserted into the through hole 26a of each thermoelectric conversion module 50, and the rod-like member 54 transects the plurality of thermoelectric conversion modules 50 and is inserted into the through hole 28a of each thermoelectric conversion module 50.

In general, for the wiring member (electrode), a metal having high conductivity or the like is used. Therefore, the wiring member has high thermal conductivity.

Therefore, in the configuration of the present invention in which the rod-like member is inserted into the through hole of the wiring member, and the wiring member and the rod-like member are brought into thermal contact with each other, the heat from the heat source is transferred to each wiring member 26 or wiring member 28 through the rod-like member 52 or the rod-like member 54, and thus the heat can he reliably transferred to the wiring member of the thermoelectric conversion module 50 positioned in the inner side in a case of overlapping the thermoelectric conversion modules 50 without being thermally insulated by the insulating substrate 12 or the like. Accordingly, a large temperature difference can he generated in the thermoelectric conversion element 10 of the thermoelectric conversion module 50 positioned in the inner side, and the power generation amount of the thermoelectric conversion device 100 can be increased.

In addition, since the rod-like member which transects the plurality of thermoelectric conversion modules 50 and is inserted into the through hole of each thermoelectric conversion module 50, each thermoelectric conversion module 50 can be supported without filling a space between the thermoelectric conversion modules 50 with a filler or the like and self-supporting properties can he improved. Also, it is possible to prevent a decrease in the power generation amount due to a decrease in heat insulating properties by filling with a filler.

From the viewpoint of the rod-like member reliably transferring heat between the wiring member and the heat source, a high thermal conductivity is preferable. Specifically, the thermal conductivity of the rod-like member is preferably 10 W/(m·K) or higher and more preferably 100 W/(m·K) or higher.

In addition, from the viewpoint of the supporting the thermoelectric conversion. module 50, the material forming the rod-like member is preferably a material having a high tensile strength.

Accordingly, as the material forming the rod-like member, iron, stainless steel, aluminum, copper and the like, whose thermal conductivity is 10 W/(m·K) or higher and tensile strength is 195 N/mm² or more, are preferable. Among these, copper is more preferable from the viewpoint of being capable of performing soldering at a low temperature.

Herein, in the example shown in the drawing, the configuration in which the rod-like member 52 to be inserted into the through hole 26a formed in the wiring member 26 positioned above the thermoelectric conversion layer 16 and the rod-like member 54 to be inserted into the through hole 28a formed in the wiring member 28 positioned below the thermoelectric conversion layer 16 are provided is adopted, but there is no limitation thereto. A configuration in which any one of the rod-like members is provided may be adopted. For example, a configuration in which only the rod-like member 54 inserted into the through hole 28a of the wiring member 28 is provided, the wiring member 28 is heated with the heat from the heat source H₂ through the rod-like member 54, and the wiring member 26 side is air-cooled may be adopted.

However, from the viewpoint of being capable of generating a large temperature difference between the wiring members, a configuration in which the rod-like member 52 inserted into the through hole 26a of the wiring member 26 and the rod-like member 54 inserted into the through hole 28a of the wiring member 28 are provided is preferable.

As shown in FIG. 9B, it is preferable that the through hole is formed in each of the wiring members 26 and the wiring members 28 of all of the thermoelectric conversion elements 10 and the rod-like member is inserted into the through hole. However, there is no limitation thereto. The through hole may be formed in the wiring member of the at least one thermoelectric conversion element 10 and the rod-like member may be inserted into the through hole.

In addition, in the example shown in the drawing, a configuration in which one through hole is formed in one wiring member of one thermoelectric conversion clement 10 and the rod-like member is inserted into the through hole is adopted. However, there is no limitation thereto. A configuration in which two or more through holes are formed in one wiring member and the rod-like member is inserted into each of the two through holes may be adopted.

In addition, the rod-like member may have insulating properties or may have conductivity.

As described above, the rod-like member comes into contact with the wiring member of the thermoelectric conversion element 10 of each thermoelectric conversion module 50. However, in a case where the rod-like member has insulting properties, each thermoelectric conversion module 50 is not electrically connected to each other and does not affect each other.

On the other hand, in a case where the rod-like member has conductivity, each thermoelectric conversion module 50 in the thermoelectric conversion device 100 preferably has the same electrical configuration and the rod-like member is preferably inserted into the wiring member at the same electrical position in each thermoelectric conversion module 50. In a case where a plurality of rod-like members are provided, each rod-like member is preferably inserted into the wiring member of each thermoelectric conversion module 50 at the same electrical position. Thus, the respective thermoelectric conversion modules 50 are connected to each other in parallel.

Even in a case where the rod-like member has conductivity, the contact portion of the rod-like member with the heat source is insulated from the heat source.

In addition, it is preferable that the plurality of thermoelectric conversion modules 50 are arranged to be separated at a predetermined interval. By arranging adjacent thermoelectric conversion modules 50 with an interval, a temperature difference can be more suitably generated.

In the thermoelectric conversion device 100 shown in FIG. 9A, the plurality of thermoelectric conversion modules 50 are respectively provided as independent members but there is no limitation thereto. The plurality of thermoelectric conversion modules may be integrally provided.

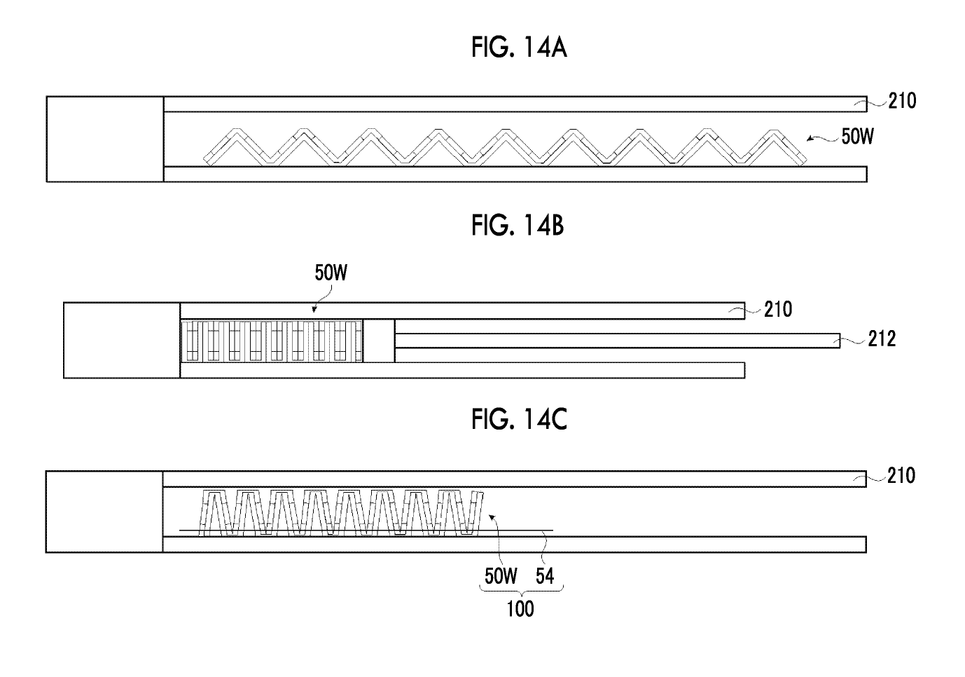

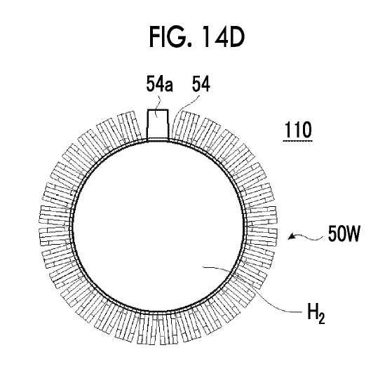

For example, a configuration in which the plurality of thermoelectric conversion modules may respectively have a configuration in which one of adjacent thermoelectric conversion modules and a substrate are bonded at one end (for example, upper end portion) in the second direction, and the other of the adjacent thermoelectric conversion modules and the substrate are bonded at the other end (for example, lower end portion) in the second direction may be adopted. That is, the plurality of thermoelectric conversion modules may be formed in a so-called bellows-like shape in which the upper end portions and the lower end portions of adjacent thermoelectric conversion modules are alternately bonded to the substrate (refer to FIG. 14C). As described above, the thermoelectric conversion device of the present invention may be formed with the configuration in which the plurality of thermoelectric conversion modules 50 are connected to each other in a bellows-like shape.

In addition, it is preferable that the rod-like member and the wiring member in which the through hole into which the rod-like member is inserted is formed are soldered.

By soldering the rod-like member and the wiring member, it is possible to further effectively transfer heat between the rod-like member and the wiring member since the contact area of the rod-like member and the wiring member is increased.

In addition, since each thermoelectric conversion module is fixed to the rod-like member, self-supporting properties can be improved.

The solder material in a case of soldering the rod-like member and the wiring member is not limited and may he appropriately selected according to the material for the rod-like member, the material for the wiring member, and the like.

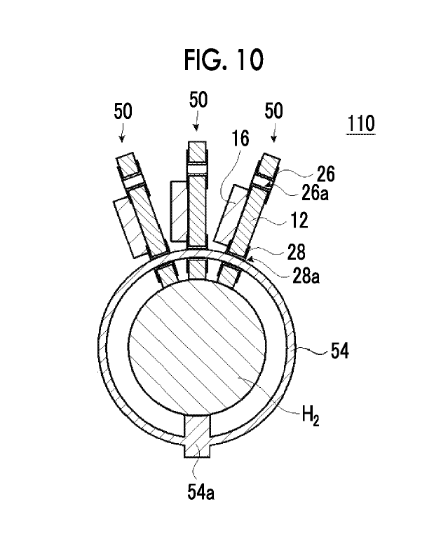

In addition, as in a thermoelectric conversion device 110 shown in FIG. 10, a configuration in which the plurality of thermoelectric conversion modules 50 may be arranged along the curve of the rod-like member 54 using the curved rod-like member 54 may be adopted.

As described above, as the configuration in which the plurality of thermoelectric conversion modules 50 are arranged along the curve of the rod-like member 54 using the curved rod-like member 54, as shown in FIG. 10, the thermoelectric conversion device 110 can be arranged by being wound around a pipe which becomes a heat source H₂ by bending the thermoelectric conversion device 110.

In addition, as shown in. FIG. 10, the rod-like member 54 of the thermoelectric conversion device 110 has a contact portion 54a with the heat source H₂ and the contact portion 54a comes into contact with the heat source H₂.

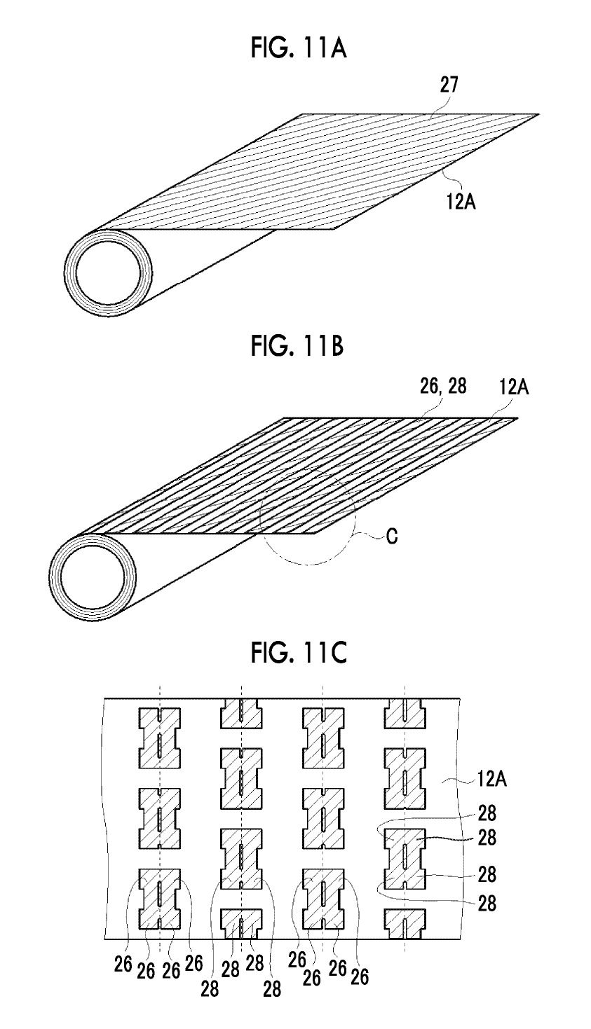

Hereinafter, using FIGS. 11A to 14C, an example of a method of manufacturing the thermoelectric conversion device will be described.

The manufacturing method described below is a method including forming the wiring member and the thermoelectric conversion layer 16 on the long insulating substrate 12 with a predetermined pattern by a roll to roll process (hereinafter, also referred to as an R to R process), and then bending the insulating substrate 12 at the predetermined pattern to produce the thermoelectric conversion device 100 in a state in which the plurality of thermoelectric conversion modules 50 are connected to each other in a bellows-like shape.

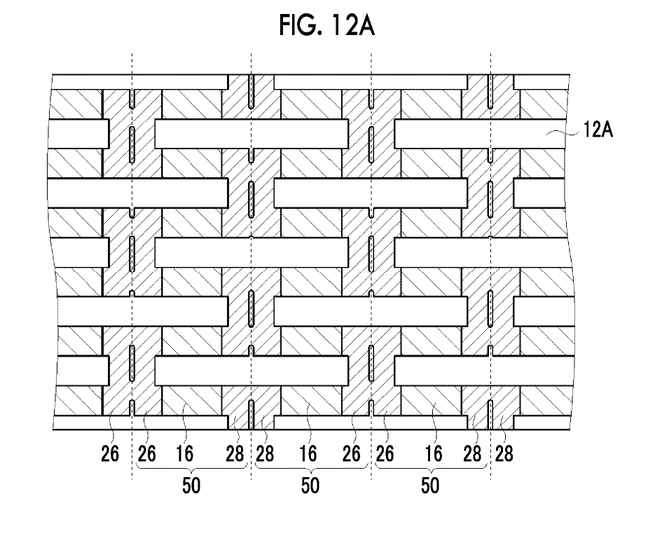

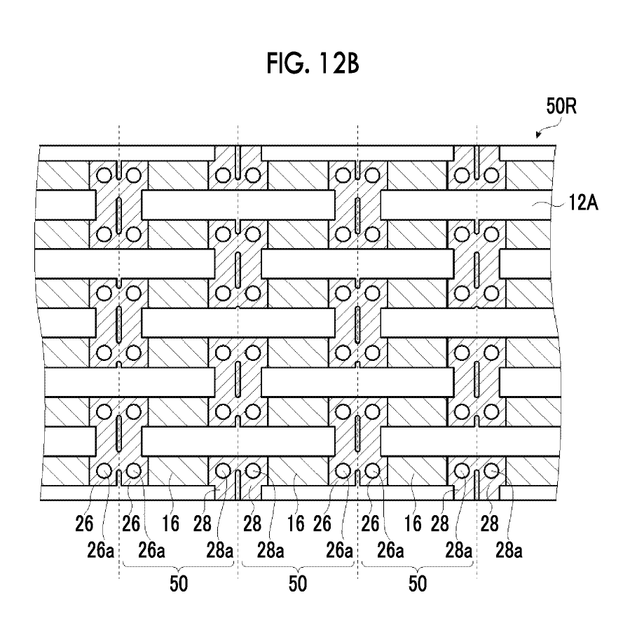

In FIGS. 11A to 12B, hatching is attached to some parts for description.

First, as shown in FIG. 11A, a sheet-like material on which a metal toil 27 is formed is prepared on the entire surface of a long substrate band 12A which becomes the insulating substrate 12 of each of the plurality of thermoelectric conversion modules 50. Such a film-like material may be produced by forming the metal foil 27 on a resin film which becomes the insulating substrate 12 by a vacuum vapor deposition method, various printing methods, and the like, or a commercially available product may be used.

Next, as shown in FIG. 11B, the sheet-like material is fed from a substrate roll formed by winding the sheet-like material on which the metal foil 27 is formed on the substrate band 12A, and while the sheet-like material is being transported in a predetermined transport path by a R to R process, the metal foil 27 is etched in a predetermined pattern to remove unnecessary portions, thereby forming the wiring member (wiring member 26, wiring member 28).

FIG. 11C shows a top view of the substrate band 12A on which wiring members are formed by etching the metal foil 27 in a predetermined pattern.

As shown in FIG. 11C, the wiring members are arranged at predetermined intervals in the width direction of the substrate band 12A and are connected to one side of an adjacent wiring member in the width direction. That is, the wiring members are formed such that every other wiring members are connected to each other in the width direction. At this time, sets of wiring members of the wiring members 26 and the wiring members 28 to be connected to each other are arranged to be shifted in the width direction.

In addition, two wiring members 26, and two wiring members 28 are alternately arranged to be separated at a predetermined distance in the transport direction of the substrate band 12A, Two wiring members 26 are arranged in a state in which the two wiring members are in contact with each other, and two wiring members 28 are also arranged in a state in which the two wiring members are in contact with each other.

Accordingly, as shown in the drawing, the wiring members are arranged at predetermined intervals in the width direction in a state in which four wiring members are bonded and are alternately arranged at a position of a half of the arrangement interval in the transport direction, that is, arranged in so-called zigzag,

Herein, as described later, the substrate band 12A is bent at a position indicated by a broken line in FIG. 11C and each region between the broken lines functions as the insulating substrate 12 of the thermoelectric conversion module 50. The width direction of the substrate band 12A is a horizontal direction (first direction) of the insulating substrate 12, the transport direction of the substrate band 12A is a vertical direction (second direction) of the insulating substrate 12, and the position of the broken line is an end portion of the insulating substrate 12 in the vertical direction. Accordingly, the wiring members are arranged on both end portions of the insulating substrate 12 in the vertical direction and at predetermined intervals in the horizontal direction, and the wiring member 26 and the wiring member 28 facing each other in the vertical direction form a set of wiring members for forming one thermoelectric conversion element 10.

In addition, as shown in FIG. 11C, in order to make the stiffness of the bending position of the wiring member indicated by the broken line lower than that of other positions and to allow easy bending at this position, a portion having a metal foil and a portion not having a metal foil are alternately formed in the width direction. Hereinafter, a portion in which the portion having a metal foil and the portion not having a metal foil are alternately formed in the width direction is referred to as a low stiffness portion.

In the above-described example, the wiring member is formed by etching the metal foil 27 laminated on the insulating substrate 12 (substrate band 12A) in a predetermined pattern. However, there is no limitation thereto. A predetermined pattern may be directly formed on the insulating substrate 12 by a method such as a vacuum vapor deposition method using a. metal mask, screen printing, metal mask printing, or ink jet printing.

Next, as shown in FIG. 12A, while the substrate band 12A on which the wiring member is formed in a predetermined shape is being transported in a predetermined transport path by an R to R process, the thermoelectric conversion layer 16 is formed in a predetermined pattern in a region between the wiring member 26 and the wiring member 28.

Although not Shown in the drawing, the P-type thermoelectric conversion layer and the N-type thermoelectric conversion layer are alternately formed in the width direction of the substrate band 12A on the thermoelectric conversion layer 16. In addition, the thermoelectric conversion layer 16 is electrically connected to the wiring member formed so as to cover the end portion of the wiring member.

The formation of the P-type thermoelectric conversion layer and the N-type thermoelectric conversion layer may be performed by a printing method such as screen printing or metal mask printing as described above, and for example, after the P-type thermoelectric conversion layer is formed, the N-type thermoelectric conversion layer may be formed.

In addition, in a case where the P-type thermoelectric conversion layer and the N-type thermoelectric conversion layer are formed of an inorganic material, the P-type thermoelectric conversion layer and the N-type thermoelectric conversion layer may be formed by sputtering or vacuum vapor deposition.

Next, as shown in FIG. 12B, the through hole which penetrates the wiring member and the substrate band 12A is formed at the position of each wiring member.

Specifically, as shown in the drawing, one through hole is formed approximately at the center of each wiring member.

The through hole can be formed by numerically controlled (NC) drilling, laser processing, chemical etching, plasma etching or the like as described above.

Thus, a module band 50R in which the plurality of thermoelectric conversion modules 50 having the plurality of thermoelectric conversion elements 10 arranged on the insulating substrate 12 at predetermined intervals in the horizontal direction, in which the plurality of thermoelectric conversion elements 10 are connected to each other in series are connected is produced.

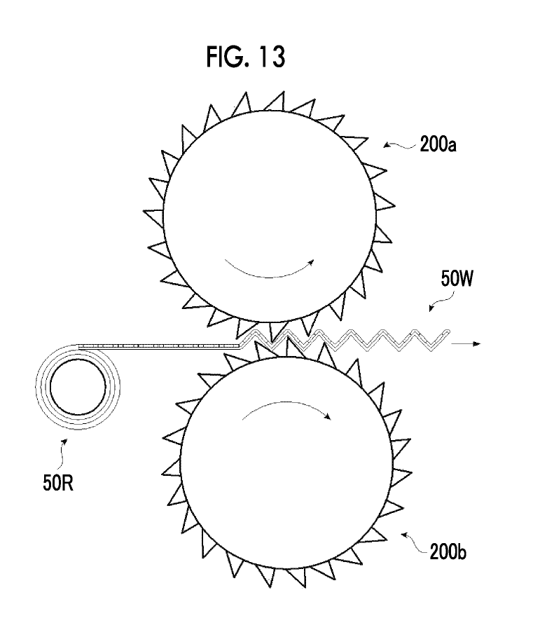

Next, as shown in FIG. 13, the module band 50R is pulled from the roll formed by winding the module band 50R, while transporting the module band in the longitudinal direction, the module band 50R is subjected to bending processing by allowing the module band to pass between a gear 200a and a gear 200b engaged with each other with a pitch according to the length of the insulating substrate 12 in the vertical direction (that is, a distance between the broken lines in FIG. 12B), and thus a bellows-like module band 50W is produced.

As described above, the low stiffness portion parallel with the width direction is formed on the wiring member on the substrate band 12A. In addition, the gear 200a and the gear 200b have a pitch according to the interval between the low stiffness portions. Accordingly, the module band 50R is bent to alternately form a mountain fold and a valley fold at the position of each low stiffness portion to produce a bellows-like module hand SOW in which the positions of the top portions of all of the mountain fold portions and the bottom portions of all of the valley fold portions are aligned.

Further, if necessary, as shown in FIG. 14A, the bent state of the bellows-like module band 50W may be controlled by inserting the bellows-like module band 50W into a guide member 210 having a space of a cross section shape according to the length of the thermoelectric conversion module 50 in the horizontal direction, that is, the interval between the low stiffness portions and the length of the thermoelectric conversion module 50 in the vertical direction and pressing the bellows-like module band 50w by a pressing member 212 as shown in FIG. 14B such that the bent bellows-like module band 50W is compressed in the longitudinal direction.

Next, as shown in FIG. 14C, the rod-like member is inserted so as to transect the through holes at the same position of each the thermoelectric conversion module 50 of the bellows-like module band 50W, and thus the thermoelectric conversion device 100 is produced.

In the example shown in the drawing, the rod-like member 54 penetrates the through holes 28a of the wiring members 28. However, the rod-like member 52 may be of course inserted into the through holes 26a of the wiring members 26.

In addition, if necessary, the rod-like member and the wiring member into which the rod-like member is inserted may be soldered.

Further, if necessary, as shown in FIG. 14D, the rod-like member 54 can be arranged to be wound around the cylindrical heat source H₂ such as a pipe by curving the rod-like member, and thus the curved thermoelectric conversion device 110 may be formed.

As described above, the thermoelectric conversion device using the bellows-like module band 50W in which the plurality of thermoelectric conversion modules 50 are connected to each other and formed in a bellows-like shape can be manufactured with high productivity by using an R to R process.

In addition, since the R to R process can be used, for example, an intermediate structure such as the substrate band 12A on which the wiring member is formed, the module band 50R on which the thermoelectric conversion layer 16 is formed, or the like in the production of the bellows-like module band 50W can he handled in a rolled state in which the intermediate structure is wound. Therefore, it is possible to secure good handleability even in a case where the insulating substrate 12 is a thin film having a thickness of 15 μm or less.

In the example of the method of manufacturing the above-described thermoelectric conversion device, the wiring member, the thermoelectric conversion layer 16, and the through hole are formed on the insulating substrate 12 (substrate band 12A) in this order, but there is no limitation thereto. For example, after the through hole is formed, the wiring member may he formed and the thermoelectric conversion layer 16 may be formed.

Such a thermoelectric conversion device can be used for various applications.

For example, various power generation applications such as power generators such as a hot spring heat generator, a solar heat power generator, and a waste heat power generator, power supplies for various devices such as a power supply for a wrist watch, a power supply for driving a semiconductor, and a power supply for a small-sized sensor may be exemplified. As the application of the thermoelectric conversion element of the present invention, in addition to power generation applications, sensor element applications such as a thermal sensor and a thermocouple may be exemplified.

While the thermoelectric conversion device of the present invention has been described above in detail, the present invention is not limited to the above-described examples and various improvements and modifications may of course be made without departing from the spirit of the present invention.

### EXPLANATION OF REFERENCES

10: thermoelectric conversion element

11a: bellows-like module band

11b: module band

12: insulating substrate

12A: substrate band

13: plate-like portion

14p: P-type thermoelectric conversion layer

16: thermoelectric conversion layer

16n: N-type thermoelectric conversion layer

18, 26, 28: wiring member

20: reinforcing member

22, 26a, 28a: through hole

50: thermoelectric conversion module

50R: module band

50W: bellows-like module band

52, 54: rod-like member

70: wire (linear member)

72: end portion fixing member

74: heat transfer member

76: magnet

100, 110, 120a to 120d: thermoelectric conversion device

200a, 200b: gear

What is claimed is:

1. A thermoelectric conversion device comprising:
a bellows-like module band which includes an insulating substrate, a plurality of thermoelectric conversion layers arranged at intervals set in advance on a principal surface of the insulating substrate, and a plurality of wiring members arranged to sandwich each of the thermoelectric conversion layers therebetween on the principal surface of the insulating substrate, is alternately mountain-folded or valley-folded and formed in a bellows structure, and has a plurality of through holes formed in each of a plurality of plate-like portions formed by bellows-like folding of the insulating substrate;
a linear member which transects the plurality of plate-like portions and is inserted into the plurality of through holes; and
wherein the linear member has flexibility.

2. The thermoelectric conversion device according to claim 1,
wherein the plurality of plate-like portions are pressed in a lamination direction by the linear member.

3. The thermoelectric conversion device according to claim 1, further comprising:
a heat transfer member which is arranged between at least some of the plate-like portions adjacent to each other.

4. The thermoelectric conversion device according to claim 2, further comprising:
a heat transfer member which is arranged between at least some of the plate-like portions adjacent to each other.

5. The thermoelectric conversion device according to claim 1, further comprising:
magnets which are arranged in a direction in which the plurality of plate-like portions are laminated to sandwich the bellows-like module band therebetween.

6. The thermoelectric conversion device according to claim 4, further comprising:
magnets which are arranged in a direction in which the plurality of plate-like portions are laminated to sandwich the bellows-like module band therebetween.

7. The thermoelectric conversion device according to claim 1,
wherein the through hole is formed in a place of the plate-like portion other than a position where the thermoelectric conversion layer is formed.

8. The thermoelectric conversion device according to claim 6,
wherein the through hole is formed in a place of the plate-like portion other than a position where the thermoelectric conversion layer is formed.

9. The thermoelectric conversion device according to claim 1,
wherein the through hole is formed in a place of the plate-like portion other than a position where the wiring member is formed.

10. The thermoelectric conversion device according to claim 8,
wherein the through hole is formed in a place of the plate-like portion other than a position where the wiring member is formed.

11. The thermoelectric conversion device according to claim 1,
wherein as seen from the direction in which the plurality of plate-like portions are laminated, the plurality of through holes formed in each of the plate-like portions are formed at positions where the through holes are overlapped each other.

12. The thermoelectric conversion device according to claim 10,
wherein as seen from the direction in which the plurality of plate-like portions are laminated, the plurality of through holes formed in each of the plate-like portions are formed at positions where the through holes are overlapped each other.

13. The thermoelectric conversion device according to claim 1,
wherein each of the plate-like portions has two or more through holes, and
two or more linear members which are respectively inserted into each of the through holes of the plate-like portions are provided.

14. The thermoelectric conversion device according to claim 12,
wherein each of the plate-like portions has two or more through holes, and
two or more linear members which are respectively inserted into each of the through holes of the plate-like portions are provided.

15. The thermoelectric conversion device according to claim 1,
wherein the through hole is formed on a mountain fold side or a valley fold side of the plate-like portion.

16. The thermoelectric conversion device according to claim 14,
wherein the through hole is formed on a mountain fold side or a valley fold side of the plate-like portion.

17. The thermoelectric conversion device according to claim 1,
wherein the plurality of thermoelectric conversion layers include a P-type thermoelectric conversion layer and an N-type thermoelectric conversion layer,
any one of the P-type thermoelectric conversion layer and the N-type thermoelectric conversion layer is alternately formed on each of the plurality of plate-like portions on one surface of the insulating substrate according to the bellows-like folding, and
the wiring member connects the P-type thermoelectric conversion layer and the N-type thermoelectric conversion layer adjacent to each other.

18. The thermoelectric conversion device according to claim 16,
wherein the plurality of thermoelectric conversion layers include a P-type thermoelectric conversion layer and an N-type thermoelectric conversion layer,
any one of the P-type thermoelectric conversion layer and the N-type thermoelectric conversion layer is alternately formed on each of the plurality of plate-like portions on one surface of the insulating substrate according to the bellows-like folding, and
the wiring member connects the P-type thermoelectric conversion layer and the N-type thermoelectric conversion layer adjacent to each other.

19. The thermoelectric conversion device according to claim 1,
wherein the plurality of thermoelectric conversion layers are arranged on each of the plate-like portions in a direction parallel to a folded ridgeline of the insulating substrate.

20. The thermoelectric conversion device according to claim 18,
wherein the plurality of thermoelectric conversion layers are arranged on each of the plate-like portions in a direction parallel to a folded ridgeline of the insulating substrate.
